(19) United States
(12) Patent Application Publication
(10) Pub. No.: US 2025/0133742 A1
(43) Pub. Date: Apr. 24, 2025

(54) SEMICONDUCTOR DEVICE AND METHOD FOR MANUFACTURING THE SAME, AND ELECTRONIC SYSTEM INCLUDING SEMICONDUCTOR DEVICE

(71) Applicant: Samsung Electronics Co., Ltd., Suwon-si (KR)

(72) Inventors: Suseong Noh, Suwon-si (KR); Ilho Myeong, Suwon-si (KR); Kwang-Soo Kim, Suwon-si (KR)

(21) Appl. No.: 18/783,638

(22) Filed: Jul. 25, 2024

(30) Foreign Application Priority Data
Oct. 18, 2023 (KR) 10-2023-0139554

(51) Int. Cl. H10B 51/20; H10B 51/30

(52) U.S. Cl. CPC H10B 51/20; H10B 51/30

(57) ABSTRACT

A semiconductor device includes: a substrate, a gate stacking structure that includes a plurality of interlayer insulating layers and a plurality of gate electrodes that are alternately stacked on the substrate, a channel layer that extends in a first direction and into the gate stacking structure, where the channel layer is electrically connected to the substrate, a channel insulating layer that at least partially surrounds the channel layer, and a plurality of dielectric layers that are between the channel insulating layer and the plurality of gate electrodes, extend along a circumference of the channel layer, and are spaced apart from each other in the first direction, where each of the plurality of dielectric layers includes: a ferroelectric pattern that at least partially surrounds the channel insulating layer, and an anti-ferroelectric pattern that at least partially surrounds the ferroelectric pattern.

### CROSS-REFERENCE TO RELATED APPLICATION

This application claims priority to and the benefit of Korean Patent Application No. 10-2023-0139554 filed at the Korean Intellectual Property Office on Oct. 18, 2023, the entire contents of which are incorporated herein by reference.

### TECHNICAL FIELD

The present disclosure relates to a semiconductor device and a method for manufacturing the same, and an electronic system including the semiconductor device.

### BACKGROUND

A semiconductor memory device may be classified as a volatile memory device or a nonvolatile memory device. The volatile memory device is a memory device in which stored data disappears if power supply is interrupted. For example, the volatile memory device includes a dynamic random access memory (DRAM), a static random access memory (SRAM), or the like. The nonvolatile memory device is a memory device in which stored data does not disappear even if power supply is interrupted. For example, the nonvolatile memory device includes a programmable ROM (PROM), an erasable PROM (EPROM), an electrically programmable ROM EPROM (EEPROM), a flash memory device, or the like. A next-generation semiconductor memory device (e.g., a magnetic random access memory (MRAM), a phase-change random access memory (PRAM), or a ferroelectric random access memory (FeRAM)) having a nonvolatile property has recently been developed in line with the trend of high performance and low power of the semiconductor memory device. As high integration and high performance of the semiconductor device are desired, various studies using semiconductor devices having different characteristics are being performed.

### SUMMARY

Embodiments are to provide a semiconductor device capable of improving reliability and a data storage system including the same.

A semiconductor device according to some embodiments includes: a substrate, a gate stacking structure that includes a plurality of interlayer insulating layers and a plurality of gate electrodes that are alternately stacked on the substrate, a channel layer that extends in a first direction and into the gate stacking structure, where the channel layer is electrically connected to the substrate, a channel insulating layer that at least partially surrounds the channel layer, and a plurality of dielectric layers that are between the channel insulating layer and the plurality of gate electrodes, extend along a circumference of the channel layer, and are spaced apart from each other in the first direction, where each of the plurality of dielectric layers includes: a ferroelectric pattern that at least partially surrounds the channel insulating layer, and an anti-ferroelectric pattern that at least partially surrounds the ferroelectric pattern.

A semiconductor device according to another embodiment includes: a substrate, a gate stacking structure that includes a plurality of interlayer insulating layers and a plurality of gate electrodes that are alternately stacked on the substrate, a channel layer that extends in a first direction and into the gate stacking structure, where the channel layer is electrically connected to the substrate, a channel insulating layer that at least partially surrounds the channel layer, and a plurality of dielectric layers that are between the channel insulating layer and the plurality of gate electrodes, extend along a circumference of the channel layer, and are spaced apart from each other in the first direction, where each of the plurality of dielectric layers includes: a conductive pattern that at least partially surrounds the channel insulating layer, a ferroelectric pattern that at least partially surrounds the conductive pattern, and an anti-ferroelectric pattern between the ferroelectric pattern and a respective one of the plurality of gate electrodes.

An electronic system including the semiconductor device according to some embodiments includes: a main substrate, a semiconductor device on the main substrate, and a controller that is electrically connected to the semiconductor device, where the semiconductor device includes: a peripheral circuit region, a cell region that includes an input/output connection wire that is electrically connected to the peripheral circuit region, and an input/output pad that is electrically connected to the input/output connection wire and extends into the cell region, where the cell region includes: a substrate, a gate stacking structure that includes a plurality of interlayer insulating layers and a plurality of gate electrodes that are alternately stacked on the substrate, a channel layer that extends in a first direction and into the gate stacking structure, where the channel layer is electrically connected to the substrate, a channel insulating layer that at least partially surrounds the channel layer, and a plurality of dielectric layers that are between the channel insulating layer and the plurality of gate electrodes, extend along a circumference of the channel layer, and are spaced apart from each other in the first direction, and where each of the plurality of dielectric layers includes a ferroelectric pattern that at least partially surrounds the channel insulating layer and an anti-ferroelectric pattern that at least partially surrounds the ferroelectric pattern.

According to the embodiments, the reliability of a semiconductor device may be improved.

### BRIEF DESCRIPTION OF THE DRAWINGS

FIG. 1 and FIG. 2 are cross-sectional views showing a semiconductor device according to some embodiments.

FIG. 3 and FIG. 4 are cross-sectional views showing various examples of a channel structure included in the semiconductor device shown in FIG. 1.

FIG. 5 is an enlarged cross-sectional view of a region (S1) of FIG. 2.

FIG. 6 is a perspective view showing the channel structure of the semiconductor device according to some embodiments.

FIGS. 7, 8, 9, 10, and 11 are cross-sectional views showing a semiconductor device according to some embodiments and corresponding to the region (S1) of FIG. 2.

FIG. 12 is a cross-sectional view showing a semiconductor device according to some embodiments.

FIG. 13 and FIG. 14 are cross-sectional views of intermediate steps sequentially showing a method for manufacturing the semiconductor device according to some embodiments.

FIGS. 15, 16, 17, 18, 19, 20, 21, 22, 23, and 24 are cross-sectional views sequentially showing the method for manufacturing the semiconductor device according to some embodiments and corresponding to a region (S2) of FIG. 14.

FIGS. 25, 26, 27, and 28 are cross-sectional views sequentially showing the method for manufacturing the semiconductor device according to some embodiments and corresponding to the region (S2) of FIG. 14.

FIG. 29 is a view schematically showing an electronic system including the semiconductor device according to some embodiments.

FIG. 30 is a perspective view schematically showing an electronic system including the semiconductor device according to some embodiments.

FIG. 31 and FIG. 32 are cross-sectional views schematically showing a semiconductor package according to some embodiments, respectively.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, or substrate is referred to as being “on” or “above” another element, it may be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side. The term “connected” may be used herein to refer to a physical and/or electrical connection and may refer to a direct or indirect physical and/or electrical connection. Components or layers described with reference to “overlap” in a particular direction may be at least partially obstructed by one another when viewed along a line extending in the particular direction or in a plane perpendicular to the particular direction.

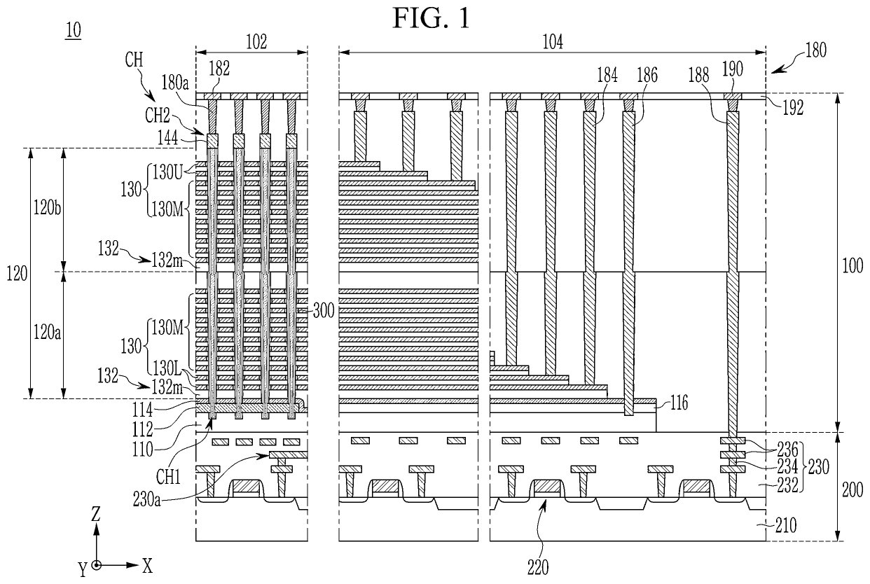

Hereinafter, a semiconductor device according to some embodiments will be described with reference to FIGS. 1 to 6.

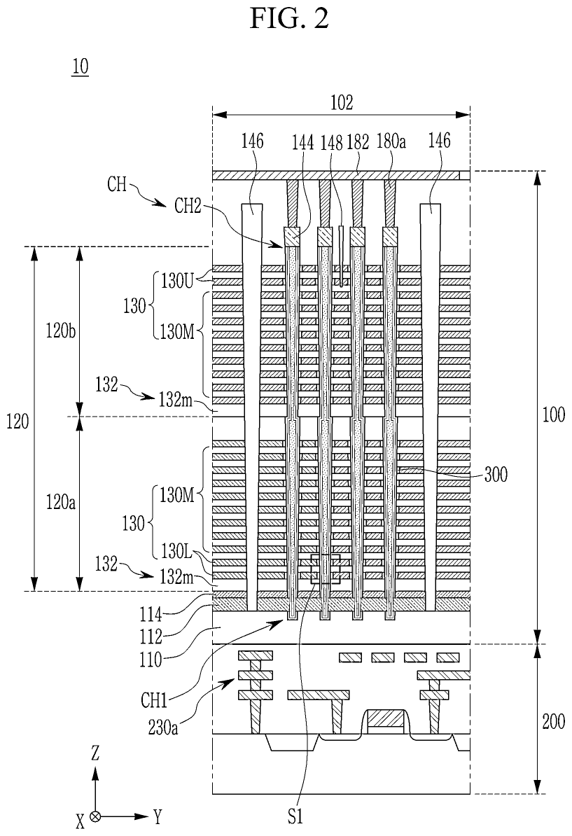

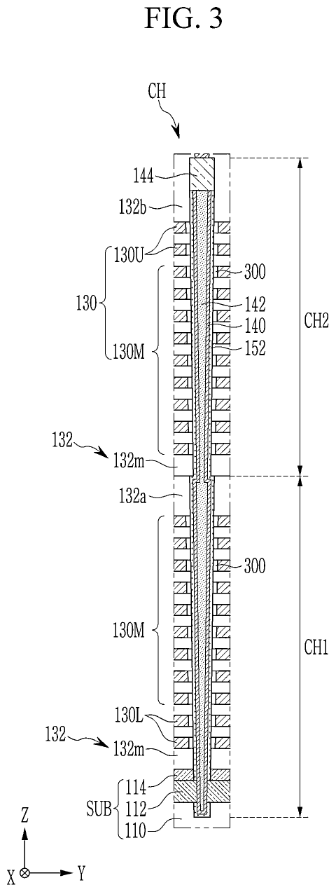

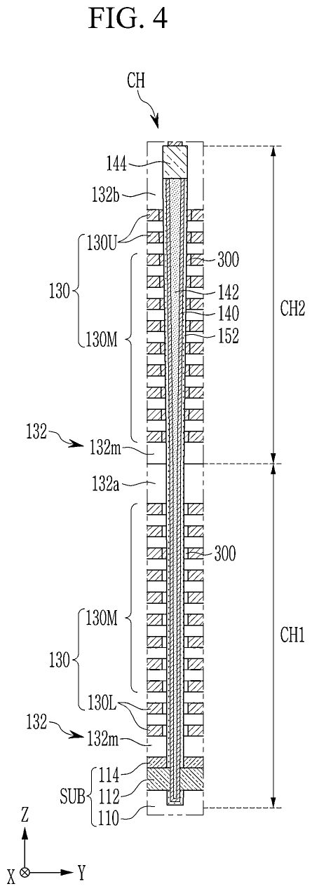

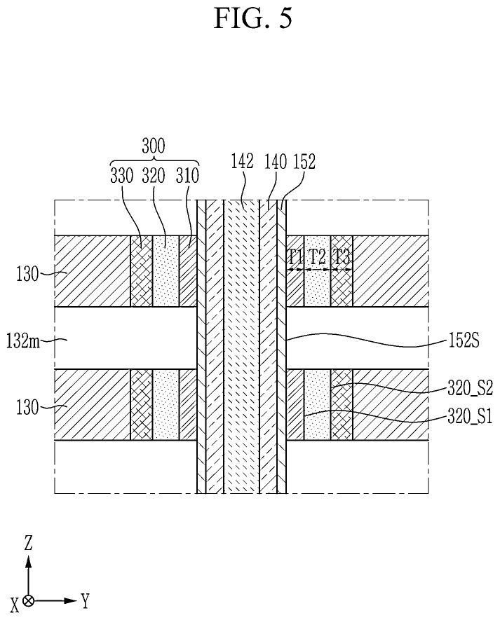

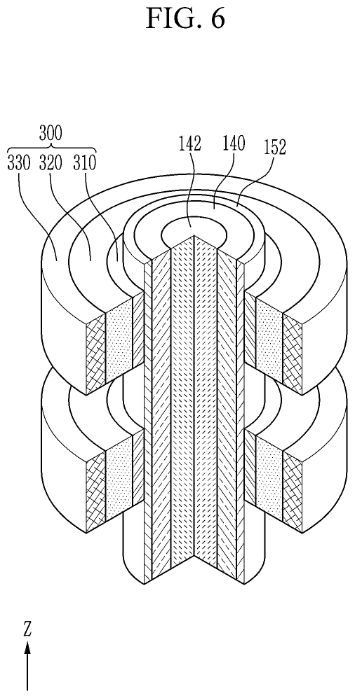

FIG. 1 and FIG. 2 are cross-sectional views showing a semiconductor device according to some embodiments. FIG. 3 and FIG. 4 are cross-sectional views showing various examples of a channel structure included in the semiconductor device shown in FIG. 1. FIG. 5 is an enlarged cross-sectional view of a region S1 of FIG. 2. FIG. 6 is a perspective view showing the channel structure of the semiconductor device according to some embodiments.

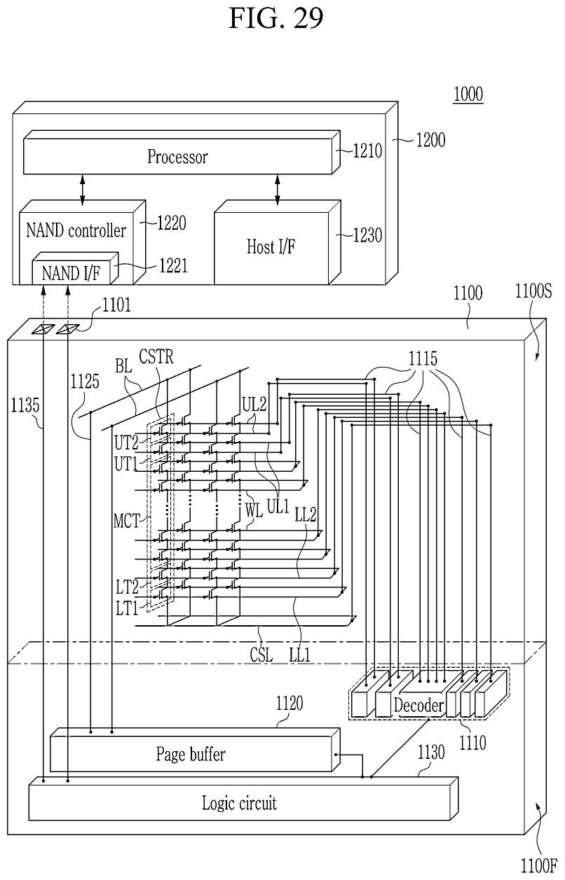

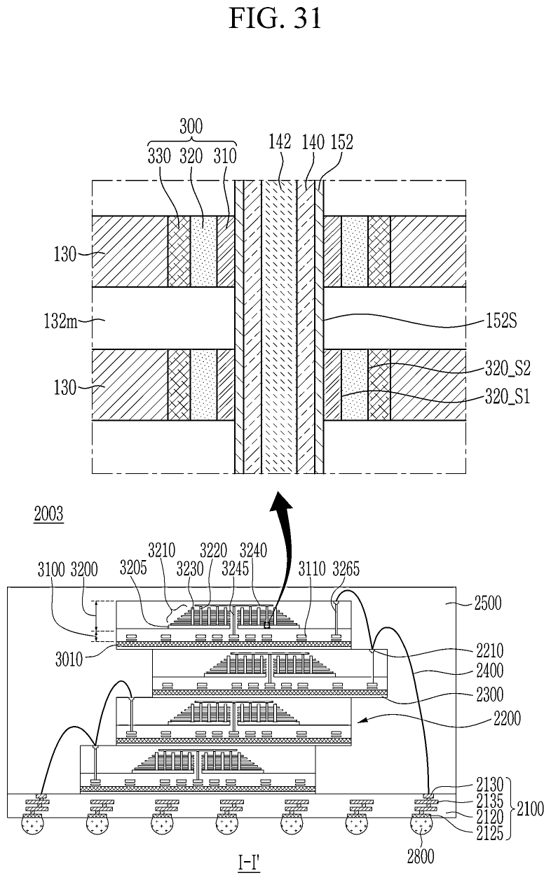

Referring to FIG. 1 and FIG. 2, the semiconductor device 10 according to some embodiments may include a cell region 100 in which a memory cell structure is provided and a circuit region 200 in which a peripheral circuit structure that controls an operation of the memory cell structure is provided. As an example, the circuit region 200 and the cell region 100 may be portions respectively corresponding to a first structure 1100F and a second structure 1100S of a semiconductor device 1100 included in an electronic system 1000 shown in FIG. 29. Alternatively, the circuit region 200 and the cell region 100 may be portions respectively corresponding to a first structure 3100 and a second structure 3200 of a semiconductor chip 2200 shown in FIG. 31.

Here, the circuit region 200 may include the peripheral circuit structure disposed above or on a first substrate 210, and the cell region 100 may include the memory cell structure that includes a gate stacking structure 120 and the channel structure CH disposed above a second substrate 110 of a cell array region 102. A first wiring portion 230 electrically connected to the peripheral circuit structure may be disposed at the circuit region 200, and a second wiring portion 180 electrically connected to the memory cell structure may be disposed at the cell region 100.

In some embodiments, the cell region 100 may be disposed on the circuit region 200. Thus, an area corresponding to the circuit region 200 may not need to be secured separately from the cell region 100 so that an area of the semiconductor device 10 is reduced. However, the present disclosure is not limited thereto, and the circuit region 200 may be disposed next to the cell region 100. Various other changes are possible.

The circuit region 200 may include the first substrate 210, and a circuit element 220 and the first wiring portion 230 disposed on the first substrate 210.

The first substrate 210 may be a semiconductor substrate including a semiconductor material. For example, the first substrate 210 may be the semiconductor substrate made of the semiconductor material, or may be a semiconductor substrate with a semiconductor layer formed on a base substrate. As an example, the first substrate 210 may include silicon, epitaxial silicon, germanium, silicon-germanium, silicon on insulator (SOI), germanium on insulator (GOI), or the like.

The circuit element 220 formed on the first substrate 210 may include various circuit elements that control an operation of the memory cell structure included in the cell region 100. As an example, the circuit element 220 may constitute the peripheral circuit structure such as a decoder circuit 1110 of FIG. 29, a page buffer 1120 of FIG. 29, a logic circuit 1130 of FIG. 29, or the like.

For example, the circuit element 220 may include a transistor, but the present disclosure is not limited thereto. For example, the peripheral circuit element 220 may include an active element, such as a transistor or the like, as well as a passive element, such as a capacitor, a resistor, an inductor, or the like.

The first wiring portion 230 disposed on the first substrate 210 may be electrically connected to the circuit element 220. In some embodiments, the first wiring portion 230 may include a plurality of wiring layers 236 that are spaced apart from each other with a first insulating layer 232 interposed therebetween and are connected to form a desired path by a contact via 234. The wiring layer 236 or the contact via 234 may include various conductive materials, and the first insulating layer 232 may include various insulating materials.

The cell region 100 of the semiconductor device 10 according to some embodiments may include the second substrate 110, the gate stacking structure 120, the channel structure CH, and a gate contact portion 184.

The second substrate 110 may include the cell array region 102 and a contact region 104. The gate stacking structure 120 and the channel structure CH may be disposed above the second substrate 110 in the cell array region 102. A structure for connecting the gate stacking structure 120, the gate contact portion 184 for connecting the gate stacking structure 120 of the cell array region 102 to the circuit region 200 or an external circuit, and/or the channel structure CH to the circuit region 200 or an external circuit, may be disposed above or on the second substrate 110 in the contact region 104.

At least a portion of the first insulating layer 232 may be disposed between the second substrate 110 and the first wiring portion 230. The portion of the first insulating layer 232 disposed between the second substrate 110 and the first wiring portion 230 may be formed of a single layer or multiple layers. For example, a layer including silicon nitride and a layer including silicon oxide may be disposed between the second substrate 110 and the first wiring portion 230. In this case, the layer including silicon oxide may be disposed on the layer including silicon nitride.

The gate stacking structure 120 including a cell insulating layer 132 and a plurality of gate electrodes 130 alternately stacked above or on a first surface (e.g., a front surface or an upper surface) of the second substrate 110, and the channel structure CH penetrating or extending into the gate stacking structure 120 to extend in a direction (e.g., a third direction (a Z direction)) crossing or intersecting the second substrate 110, may be disposed at the cell array region 102.

The second substrate 110 may include a semiconductor material (e.g., polysilicon). For example, the second substrate 110 may include polysilicon doped with an impurity. However, the present disclosure is not limited thereto, and for example, the second substrate 110 may include a metal material or metal silicide.

The semiconductor device 10 according to some embodiments may further include a first horizontal conductive layer 112 and a second horizontal conductive layer 114.

In the cell array region 102, the first horizontal conductive layer 112 may be disposed on the second substrate 110. The first horizontal conductive layer 112 may electrically connect the channel structure CH to the second substrate 110. The first horizontal conductive layer 112 may function as a portion of a common source line (e.g., see CSL of FIG. 29) of the semiconductor device 10. For example, the first horizontal conductive layer 112 may function as the common source line together with the second substrate 110.

The first horizontal conductive layer 112 may be penetrated or extended into by the channel structure CH. In this case, a ferroelectric pattern 320 and a channel insulating layer 152 of the channel structure CH may be removed from a portion where the first horizontal conductive layer 112 is disposed, so that the first horizontal conductive layer 112 is connected to a channel layer 140. That is, the first horizontal conductive layer 112 may directly contact the channel layer 140. Accordingly, the first horizontal conductive layer 112 may electrically connect the second substrate 110 and the channel layer 140.

In one variation, the first horizontal conductive layer 112 may not be provided between the second substrate 110 and the gate stacking structure 120 in some regions of the contact region 104. In this case, a horizontal insulating layer 116 may be provided between the second substrate 110 and the gate stacking structure 120. The horizontal insulating layer 116 may include various insulating materials. For example, the horizontal insulating layer 116 may include silicon oxide (SiO₂) and/or silicon nitride (SiN). The horizontal insulating layer 116 may be a material remaining in some regions of the contact region 104 during a replacement process for forming the first horizontal conductive layer 112. The horizontal insulating layer 116 may be made of multiple layers, but the present disclosure is not limited thereto.

The second horizontal conductive layer 114 may be disposed on the first horizontal conductive layer 112 and the horizontal insulating layer 116. The second horizontal conductive layer 114 may extend along a first direction (e.g., an X direction) and a second direction (e.g., a Y direction) in the cell array region 102 and the contact region 104. The second horizontal conductive layer 114 may electrically connect the channel structure CH and the second substrate 110 together with the first horizontal conductive layer 112. The second horizontal conductive layer 114 may function as a portion of the common source line of the semiconductor device 10. The second horizontal conductive layer 114 may be penetrated or extended into by the channel structure CH.

The second horizontal conductive layer 114 may be used as a support layer for preventing a mold stack from collapsing or falling during the replacement process for forming the first horizontal conductive layer 112.

Each of the first and second horizontal conductive layers 112 and 114 may include a semiconductor material (e.g., polysilicon). For example, the first horizontal conductive layer 112 may include polysilicon doped with an impurity, and the second horizontal conductive layer 114 may include polysilicon doped with an impurity or may be a layer including an impurity diffused from the first horizontal conductive layer 112. However, the present disclosure is not limited thereto, and the second horizontal conductive layer 114 may include an insulating material. Alternatively, the second horizontal conductive layer 114 may not be separately provided.

The gate stacking structure 120 in which the cell insulating layer 132 and the plurality of gate electrodes 130 are alternately stacked may be disposed on the second substrate 110 (for example, on the second horizontal conductive layer 114 of the second substrate 110).

In some embodiments, the gate stacking structure 120 may include a plurality of gate stacking structures 120a and 120b sequentially stacked on the second substrate 110. Then, the number of the stacked gate electrodes 130 may be increased so that the number of memory cells is increased with a stable structure. For example, the gate stacking structure 120 may include the first and second gate stacking structures 120a and 120b to increase data storage capacity while simplifying a structure of the present disclosure. However, the present disclosure is not limited thereto, and the gate stacking structure 120 may include one gate stacking structure or may include three or more gate stacking structures.

The plurality of gate electrodes 130 in the gate stacking structure 120 may include a lower gate electrode 130L, a memory cell gate electrode 130M, and an upper gate electrode 130U sequentially disposed above the second substrate 110. The lower gate electrode 130L may be used as a gate electrode of a ground selection transistor, the memory cell gate electrode 130M may constitute the memory cell, and the upper gate electrode 130U may be used as a gate electrode of a string selection transistor. The number of memory cell gate electrodes 130M may be determined depending on the data storage capacity of the semiconductor device 10. According to some embodiments, one or two or more lower gate electrodes 130L and one or two or more upper gate electrodes 130U may be provided, and each of the lower gate electrode and the upper gate electrode may have the same structure as or a different structure from the memory cell gate electrode 130M. Further, a portion (e.g., the memory cell gate electrode 130M adjacent to the lower gate electrode 130L and the upper gate electrode 130U) of the plurality of gate electrodes 130 may be a dummy gate electrode.

The cell insulating layer 132 may include a plurality of interlayer insulating layers 132m disposed at lower portions of the plurality of gate electrodes 130 or between two adjacent gate electrodes 130 within the first and second gate stacking structures 120a and 120b, and upper insulating layers 132a and 132b disposed at upper portions of the first and second gate stacking structures 120a and 120b. For example, the upper insulating layers 132a and 132b may include the first upper insulating layer 132a disposed at an upper portion of the first gate stacking structure 120a and the second upper insulating layer 132b disposed at an upper portion of the second gate stacking structure 120b. In this case, the first upper insulating layer 132a may be an intermediate insulating layer disposed between the first gate stacking structure 120a and the second gate stacking structure 120b, and the second upper insulating layer 132b may be an uppermost insulation layer disposed at an uppermost portion of the gate stacking structure 120. The second upper insulating layer 132b may constitute a portion or all of a cell region insulating layer disposed entirely at an upper portion of the cell region 100. In some embodiments, thicknesses of a plurality of cell insulating layers 132 may not all be the same. For example, thicknesses of the upper insulating layers 132a and 132b may be greater than thicknesses of the plurality of interlayer insulating layers 132m. However, a shape, a structure, or the like of the cell insulating layer 132 may be variously modified according to some embodiments.

For simplicity of illustration, the drawings illustrate that the cell insulating layer 132 has a boundary between the first gate stacking structure 120a and the second gate stacking structure 120b in the contact region 104. However, the present disclosure is not limited thereto. A plurality of insulating layers in the contact region 104 may have various stacking structures, and the present disclosure is not limited thereto.

The plurality of gate electrodes 130 may include various conductive materials. For example, the plurality of gate electrodes 130 may include a metal material such as tungsten (W), copper (Cu), aluminum (Al), or the like. As another example, the plurality of gate electrodes 130 may include polysilicon, a metal nitride (e.g., titanium nitride (TiN), tantalum nitride (TaN), or the like), or a combination thereof. In one variation, an insulating layer including an insulating material or a portion of a dielectric layer 300 may be disposed outside the plurality of gate electrodes 130. The cell insulating layer 132 may include various insulating materials. For example, the cell insulating layer 132 may include silicon oxide, silicon nitride, silicon oxynitride, a low dielectric constant material having a lower dielectric constant than the silicon oxide, or a combination thereof.

In some embodiments, the channel structure CH may penetrate or extend into the gate stacking structure 120 to extend in the direction (e.g., the third direction (the Z direction)) crossing or intersecting the second substrate 110.

Each channel structure CH may form one memory cell string, and a plurality of channel structures CH may be spaced apart from each other while forming rows and columns on a plane. For example, the plurality of channel structures CH may be disposed in various shapes such as a lattice shape, a zigzag shape, and the like on a plane.

In some embodiments, the channel structure CH may have a pillar shape. For example, when the channel structure CH is viewed in a cross-section, the channel structure CH may have an inclined side surface so that a width of the channel structure becomes narrow as the channel structure is close to or approaches the second substrate 110 according to an aspect ratio. However, the present disclosure is not limited thereto, and a disposition, a structure, a shape, or the like of the channel structure CH may be variously modified.

The channel structure CH may penetrate or extend into the first and second horizontal conductive layers 112 and 114. The channel structure CH may be electrically connected to the first and second horizontal conductive layers 112 and 114.

Referring to FIGS. 3 to 6, the channel structure CH of the semiconductor device according to some embodiments may include the channel layer 140, the channel insulating layer 152 at least partially surrounding the channel layer 140, and the dielectric layer 300 disposed on the channel insulating layer 152 between the plurality of gate electrodes 130 and the channel insulating layer 152. The channel structure CH may further include a core insulating layer 142 disposed inside the channel layer 140, and may further include a channel pad 144 disposed on the channel layer 140.

The core insulating layer 142 may be disposed at a central region of the channel structure CH. The channel layer 140 may be disposed while at least partially surrounding a sidewall of the core insulating layer 142. That is, the channel layer 140 may at least partially surround the core insulating layer 142. For example, the core insulating layer 142 may have a pillar shape (e.g., a cylindrical shape or a polygonal pillar shape), and the channel layer 140 may have a planar shape, such as an annular shape or the like. However, the present disclosure is not limited thereto, and the core insulating layer 142 may not be provided and the channel layer 140 may have a pillar shape (e.g., a cylindrical shape or a polygonal pillar shape).

The channel layer 140 may penetrate or extend into the first and second horizontal conductive layers 112 and 114. The channel layer 140 may be electrically connected to the first and second horizontal conductive layers 112 and 114. For example, a portion of a side surface of the channel layer 140 may be electrically connected to the first horizontal conductive layer 112 by directly contacting a side surface of the first horizontal conductive layer 112.

The channel layer 140 may include a semiconductor material (for example, polysilicon). The core insulating layer 142 may include various insulating materials. For example, the core insulating layer 142 may include silicon oxide, silicon nitride, silicon oxynitride, or a combination thereof. However, materials of the channel layer 140 and the core insulating layer 142 are not limited thereto.

The channel insulating layer 152 may at least partially surround the channel layer 140. For example, the channel insulating layer 152 may extend in the third direction (the Z direction) to surround a side surface of the channel layer 140. The channel insulating layer 152 may have a planar shape, such as an annular shape or the like.

The channel insulating layer 152 may include an insulating material. For example, the channel insulating layer 152 may include a material such as silicon oxide, silicon nitride, silicon oxynitride, or the like. As an example, the channel insulating layer 152 may be formed by stacking a layer including silicon oxide and a layer including silicon nitride.

A plurality of dielectric layers 300 may be disposed on a side surface of the channel insulating layer 152. For example, the plurality of dielectric layers 300 may be disposed on an exterior side surface 152S of the channel insulating layer 152. The plurality of dielectric layers 300 may at least partially surround at least a portion of the channel insulating layer 152. The plurality of dielectric layers 300 may be disposed between the plurality of gate electrodes 130 and the channel layer 140. As an example, the plurality of dielectric layers 300 may be disposed between the plurality of gate electrodes 130 and the channel insulating layer 152. The plurality of dielectric layers 300 may be in contact with the side surface of the channel insulating layer 152 and side surfaces of the plurality of gate electrodes 130, respectively.

In some embodiments, and as shown in FIG. 6, the plurality of dielectric layers 300 may extend along a circumferential direction or a circumference of the channel structure CH. For example, the plurality of dielectric layers 300 may have an annular shape on a plane, and may surround at least a portion of the channel insulating layer 152. In other words, the plurality of dielectric layers 300 may extend along the circumferential direction or the circumference of the channel structure CH to at least partially surround a portion of the exterior side surface 152S of the channel insulating layer 152. That is, the plurality of dielectric layers 300 may cover or overlap a side surface of the channel insulating layer 152 along the circumferential direction or the circumference of the channel structure CH.

Additionally, the plurality of dielectric layers 300 may be spaced apart from each other at a predetermined interval along the third direction (the Z direction). That is, the plurality of dielectric layers 300 may be disposed apart from each other along the third direction (e.g., the Z direction). The plurality of dielectric layers 300 may be disposed between the plurality of gate electrodes 130 and the channel insulating layer 152, and may not be disposed between the plurality of interlayer insulating layers 132m and the channel insulating layer 152. Therefore, the plurality of dielectric layers 300 may be disposed between the plurality of gate electrodes 130 and the channel layer 140, and may not be disposed between the plurality of interlayer insulating layers 132m and the channel layer 140. That is, the plurality of dielectric layers 300 may overlap the plurality of gate electrodes 130 in a radius direction (e.g., a second direction, such as the Y direction) of the channel structure CH, and may not overlap the plurality of interlayer insulating layers 132m in the radius direction of the channel structure CH.

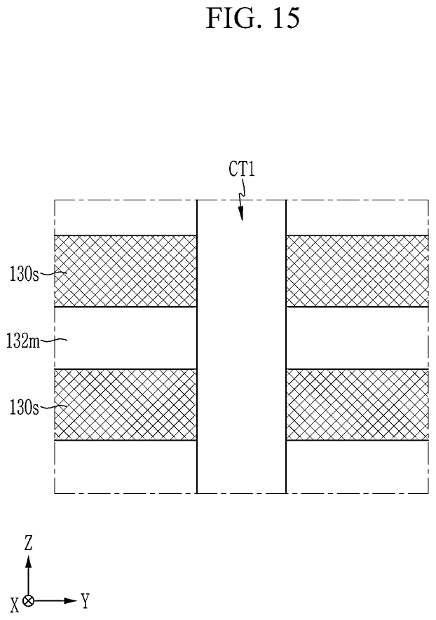

In some embodiments, upper surfaces of the plurality of dielectric layers 300 may be disposed at substantially the same level as that of an upper surface of the gate electrode 130 (e.g., the upper surfaces of the gate electrode 130 and the dielectric layers 300 extend from the second substrate 110 by a same distance). Additionally, lower surfaces of the plurality of dielectric layers 300 may be disposed at substantially the same level as that of a lower surface of the gate electrode 130 adjacent to the plurality of dielectric layers 300 (e.g., the lower surfaces of the gate electrode 130 and the dielectric layers 300 extend from the second substrate 110 by a same distance). That is, the upper surfaces of the plurality of dielectric layers 300 may be aligned with the upper surface of the gate electrode 130, and the lower surfaces of the plurality of dielectric layers 300 may be aligned with the lower surface of the gate electrode 130. This may be due to a characteristic of a process in which the plurality of dielectric layers 300 are formed within a space where portions of a plurality of sacrificial insulating layers 130s of FIG. 15 exposed by a first channel hole CT1 of FIG. 15 are removed. As used herein, “an element A that is aligned with element B” may refer to elements A and B being coplanar.

Each of the plurality of dielectric layers 300 of the semiconductor device 10 according to some embodiments may include a conductive pattern 310, the ferroelectric pattern 320, and an anti-ferroelectric pattern 330 sequentially stacked on the exterior side surface 152S of the channel insulating layer 152.

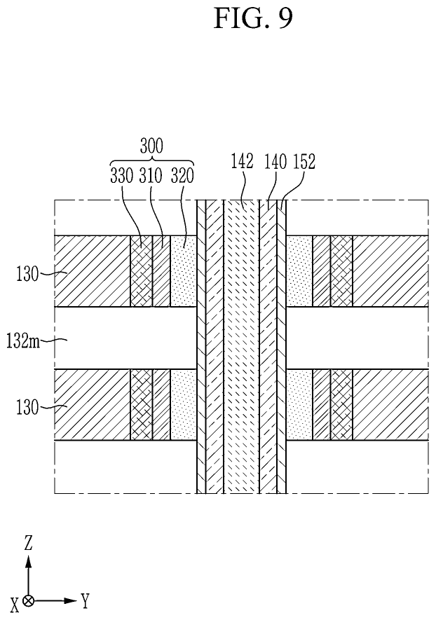

The conductive pattern 310 may be disposed on a side surface of the channel insulating layer 152. For example, the conductive pattern 310 may be disposed on the exterior side surface 152S of the channel insulating layer 152. The conductive pattern 310 may surround at least a portion of the channel insulating layer 152. The conductive pattern 310 may be disposed between the plurality of gate electrodes 130 and the channel layer 140. As an example, the conductive pattern 310 may be disposed between the ferroelectric pattern 320 that will be described later and the channel insulating layer 152. The conductive pattern 310 may contact the side surface of the channel insulating layer 152. However, the present disclosure is not limited thereto, and the conductive pattern 310 may be disposed between the ferroelectric pattern 320 and the anti-ferroelectric pattern 330. In this case, the ferroelectric pattern 320 may be disposed between the conductive pattern 310 and the channel insulating layer 152. A description of this will be provided later with reference to FIG. 9.

In some embodiments, and as shown in FIG. 6, the conductive pattern 310 may extend along a circumferential direction or a circumference of the channel structure CH. For example, the conductive pattern 310 may have an annular shape on a plane, and may surround at least a portion of the channel insulating layer 152. In other words, the conductive pattern 310 may extend along the circumferential direction or a circumference of the channel structure CH to surround a portion of the exterior side surface 152S of the channel insulating layer 152. That is, the conductive pattern 310 may cover or overlap a side surface of the channel insulating layer 152 along the circumferential direction or a circumference of the channel structure CH.

Additionally, a plurality of conductive patterns 310 may be provided to be spaced apart from each other at a predetermined interval along the third direction (e.g., the Z direction). In other words, the plurality of conductive patterns 310 may be disposed apart from each other along the third direction (e.g., the Z direction). Each of the plurality of conductive patterns 310 disposed apart from each other along the third direction (e.g., the Z direction) may surround at least a portion of the channel insulating layer 152. Specifically, the plurality of conductive patterns 310 may be disposed between the plurality of gate electrodes 130 and the channel insulating layer 152, and may not be disposed between the plurality of interlayer insulating layers 132m and the channel insulating layer 152. Accordingly, the conductive pattern 310 may be disposed between the plurality of gate electrodes 130 and the channel layer 140, and may not be disposed between the plurality of interlayer insulating layers 132m and the channel layer 140. That is, the conductive pattern 310 may overlap the plurality of gate electrodes 130 in a radius direction of the channel structure CH (e.g., the Y direction), and may not overlap the plurality of interlayer insulating layers 132m in the radius direction of the channel structure CH (e.g., the Y direction).

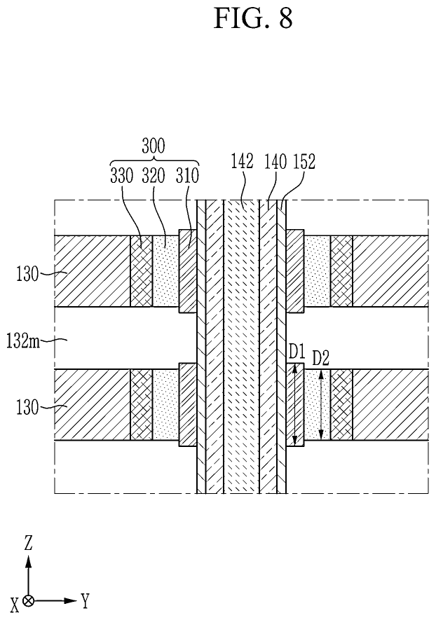

In some embodiments, an upper surface of the conductive pattern 310 may be disposed at substantially the same level as that of an upper surface of the gate electrode 130 adjacent to the conductive pattern 310. That is, a distance from the upper surface of the conductive pattern 310 to the upper surface of the gate electrode 130 adjacent to the conductive pattern 310 and a distance from the upper surface of the conductive pattern 310 to an upper surface of the second substrate 110 may be substantially the same. Additionally, a lower surface of the conductive pattern 310 may be disposed at substantially the same level as that of a lower surface of the gate electrode 130 adjacent to the conductive pattern 310. Here, the gate electrode 130 adjacent to the conductive pattern 310 may mean the gate electrode 130 that overlaps the conductive pattern 310 in the radius direction of the channel structure CH among the plurality of gate electrodes 130. Accordingly, a width of the conductive pattern 310 in the third direction (e.g., the Z direction) may be substantially the same as widths of the plurality of gate electrodes 130 in the third direction (e.g., the Z direction). This may be due to a characteristic of a process in which the conductive pattern 310 is formed within the space where the portions of the plurality of sacrificial insulating layers 130s of FIG. 15 exposed by the first channel hole CT1 of FIG. 15 are removed. However, the present disclosure is not limited thereto, and the width of the conductive pattern 310 in the third direction (the Z direction) may be greater than a width of the gate electrode 130 adjacent to the conductive pattern 310 in the third direction (the Z direction). A description of this will be provided later with reference to FIG. 8.

In some embodiments, the conductive pattern 310 may include a conductive material. For example, the conductive pattern 310 may include a metal material such as tungsten (W), rubidium (Rb), copper (Cu), aluminum (Al), or the like. As another example, the conductive pattern 310 may include a metal oxide, a metal nitride (e.g., titanium nitride (TiN), tantalum nitride (TaN), or the like), or a combination thereof.

In some embodiments, the conductive pattern 310 may include the same material as those of the plurality of gate electrodes 130. For example, the conductive pattern 310 and the plurality of gate electrodes may include tungsten (W). In this case, when a voltage is applied to the plurality of gate electrodes 130, an electric field may be greatly concentrated within the conductive pattern 310. Accordingly, a characteristic of an operating voltage for forming a remnant polarization of the ferroelectric pattern 320 in contact with the conductive pattern 310 may be improved. However, the present disclosure is not limited thereto, and the conductive pattern 310 may include a material different from those of the plurality of gate electrodes 130. In this case, when a voltage is applied to the plurality of gate electrodes 130, an electric field may be concentrated within the conductive pattern 310. A detailed description of this will be provided later in a description of the ferroelectric pattern 320.

The ferroelectric pattern 320 may be disposed on a side surface of the conductive pattern 310. For example, the ferroelectric pattern 320 may be disposed on an exterior side surface of the conductive pattern 310. The ferroelectric pattern 320 may at least partially surround the conductive pattern 310. The ferroelectric pattern 320 may be disposed between the plurality of gate electrodes 130 and the channel layer 140. As an example, the ferroelectric pattern 320 may be disposed between the conductive pattern 310 and the anti-ferroelectric pattern 330 that will be described later. The ferroelectric pattern 320 may contact the side surface of the conductive pattern 310 and a side surface of the anti-ferroelectric pattern 330. For example, an interior side surface 320_S1 of the ferroelectric pattern 320 may contact the side surface of the conductive pattern 310, and an exterior side surface 320_S2 of the ferroelectric pattern 320 may contact the side surface of the anti-ferroelectric pattern 330.

In some embodiments, and as shown in FIG. 6, the ferroelectric pattern 320 may extend along a circumferential direction or a circumference of the channel structure CH. For example, the ferroelectric pattern 320 may have an annular shape on a plane, and may at least partially surround the conductive pattern 310. In other words, the ferroelectric pattern 320 may extend along the circumferential direction of the channel structure CH to at least partially surround the exterior side surface of the conductive pattern 310. That is, the ferroelectric pattern 320 may cover or overlap the side surface of the conductive pattern 310 along the circumferential direction or a circumference of the channel structure CH.

Additionally, a plurality of ferroelectric patterns 320 may be provided to be spaced apart from each other at a predetermined interval along the third direction (e.g., the Z direction). In other words, the plurality of ferroelectric patterns 320 may be disposed apart from each other in the third direction (e.g., the Z direction). Each of the plurality of ferroelectric patterns 320 disposed apart from each other in the third direction (the Z direction) may surround the conductive pattern 310. Specifically, the plurality of ferroelectric patterns 320 may be disposed between the plurality of gate electrodes 130 and the conductive pattern 310, and may not be disposed between the plurality of interlayer insulating layers 132m and the channel insulating layer 152. Therefore, the ferroelectric pattern 320 may be disposed between the plurality of gate electrodes 130 and the channel layer 140, and may not be disposed between the plurality of interlayer insulating layers 132m and the channel layer 140. That is, the ferroelectric pattern 320 may overlap the plurality of gate electrodes 130 in a radius direction of the channel structure CH (e.g., a second direction), and may not overlap the plurality of interlayer insulating layers 132m in the radius direction of the channel structure CH. Additionally, the ferroelectric pattern 320 may overlap the conductive pattern 310 in the radius direction of the channel structure CH.

In some embodiments, an upper surface of the ferroelectric pattern 320 may be disposed at substantially the same level as that of an upper surface of the conductive pattern 310. That is, a distance from the upper surface of the ferroelectric pattern 320 to the upper surface of the conductive pattern 310 and a distance from the upper surface of the ferroelectric pattern 320 to an upper surface of the second substrate 110 may be substantially the same. Additionally, a lower surface of the ferroelectric pattern 320 may be disposed at substantially the same level as that of a lower surface of the conductive pattern 310. Accordingly, the upper surface of the ferroelectric pattern 320 and the upper surface of the conductive pattern 310 may be aligned in the radius direction of the channel structure CH. Additionally, a width of the ferroelectric pattern 320 in the third direction (the Z direction) may be substantially the same as a width of the conductive pattern 310 in the third direction (the Z direction). However, the present disclosure is not limited thereto, and the width of the ferroelectric pattern 320 in the third direction (the Z direction) may be smaller than the width of the conductive pattern 310 in the third direction (the Z direction). A description of this will be provided later with reference to FIG. 8.

Additionally, the upper surface of the ferroelectric pattern 320 may be disposed at substantially the same level as that of an upper surface of the gate electrode 130 adjacent to the ferroelectric pattern 320. That is, the upper surface of the ferroelectric pattern 320 may be aligned with the upper surface of the gate electrode 130 adjacent to the ferroelectric pattern 320. A distance from the upper surface of the ferroelectric pattern 320 to the upper surface of the gate electrode 130 adjacent to the ferroelectric pattern 320 and a distance from the upper surface of the ferroelectric pattern 320 to the upper surface of the second substrate 110 may be substantially the same. Additionally, the lower surface of the ferroelectric pattern 320 may be disposed at substantially the same level as that of a lower surface of the gate electrode 130 adjacent to the ferroelectric pattern 320. Here, the gate electrode 130 adjacent to the ferroelectric pattern 320 may mean the gate electrode 130 that overlaps the ferroelectric pattern 320 in the radius direction of the channel structure CH among the plurality of gate electrodes 130. Accordingly, the width of the ferroelectric pattern 320 in the third direction (the Z direction) may be substantially the same as widths of the plurality of gate electrodes 130 in the third direction (the Z direction). This may be due to a characteristic of a process in which the ferroelectric pattern 320 is formed within the space where the portions of the plurality of sacrificial insulating layers 130s of FIG. 15 exposed by the first channel hole CT1 of FIG. 15 are removed.

In some embodiments, a second thickness T2 in a radius direction of the channel structure CH of the ferroelectric pattern 320 may be greater than a first thickness T1 in a radius direction of the channel structure CH of the conductive pattern 310 (e.g., the second direction or Y direction). Here, and as shown in FIG. 5, the second thickness T2 in the radius direction of the channel structure CH of the ferroelectric pattern 320 may be substantially the same as a thickness of the ferroelectric pattern 320 in the second direction (the Y direction) on a cross-section including the second direction (the Y direction) and the third direction (the Z direction). That is, in the embodiment, the thickness of the ferroelectric pattern 320 in the second direction (the Y direction) may be greater than a thickness of the conductive pattern 310 in the second direction (the Y direction).

The ferroelectric pattern 320 may include a ferroelectricity material (or a ferroelectric material). For example, the ferroelectric pattern 320 may include an Hf compound having a ferroelectric characteristic. As an example, the ferroelectric pattern 320 may include HfO₂, HfZnO, HfSiO, HfSiON, HfTaO, HfTiO, HfZrO, or a combination thereof. Additionally, the ferroelectric pattern 320 may include a ferroelectricity material with a perovskite structure such as PZT (PbZrxTi1-xO₃), BaTiO₃, PbTiO₃, or the like. The ferroelectric pattern 320 may include at least one dopant selected from carbon (C), silicon (Si), magnesium (Mg), aluminum (Al), yttrium (Y), nitrogen (N), germanium (Ge), tin (Sn), strontium (Sr), lead (Pb), calcium (Ca), barium (Ba), titanium (Ti), zirconium (Zr), gadolinium (Gd), and lanthanum (La). The ferroelectric pattern 320 may be formed of a crystalline material. For example, the ferroelectric pattern 320 may have a crystal structure of an orthorhombic system.

In some embodiments, when the ferroelectric pattern 320 includes a ferroelectricity material, the ferroelectric pattern 320 may have various states of polarization depending on a voltage applied between the plurality of gate electrodes 130 and the channel layer 140. For example, if an external electric field (e.g., an electric field generated by a voltage difference applied between the plurality of gate electrodes 130 and the channel layer 140) is applied to the ferroelectric pattern 320, a remnant polarization may be generated within the ferroelectric pattern 320. In one variation, even when the external electric field (e.g., the electric field due to the voltage difference applied between the plurality of gate electrodes 130 and the channel layer 140) is not applied to the ferroelectric pattern 320, the already generated remnant polarization may be kept constant.

Here, a size of the remnant polarization generated within the ferroelectric pattern 320 may be determined by a polarization-voltage (PV) hysteresis characteristic that is based on a size of the voltage applied between the plurality of gate electrodes 130 and the channel layer 140 and a process in which the remnant polarization generated within the ferroelectric pattern 320 has progressed. The generated remnant polarization may be stored within the ferroelectric pattern 320, and signal information may be non-volatilely stored by the stored remnant polarization. In other words, the ferroelectric pattern 320 may function as a non-volatile memory layer.

In this case, according to some embodiments, when a voltage is applied to the plurality of gate electrodes 130, an electric field may be concentrated within the conductive pattern 310. In some embodiments, the conductive pattern 310 may include a conductive material so that the electric field within the conductive pattern 310 is distributed with a uniform density. Accordingly, the electric field having the uniform density may be distributed at a portion of the ferroelectric pattern 320 that overlaps the conductive pattern 310 in the radius direction of the channel structure CH, and the remnant polarization may be uniformly generated within the ferroelectric pattern 320. Therefore, the reliability of the semiconductor device 10 may be improved.

Additionally, the conductive pattern 310 and the ferroelectric pattern 320 according to some embodiments may be disposed apart from each other in the third direction (the Z direction). Specifically, the conductive pattern 310 may be disposed between the plurality of gate electrodes 130 and the ferroelectric pattern 320, and may not be disposed between the plurality of interlayer insulating layers 132m and the channel insulating layer 152. According to some embodiments, when a voltage is applied to the gate electrode 130, an electric field may be concentrated on the conductive pattern 310 disposed at one side of the gate electrode 130 to which the voltage is applied. Therefore, it is possible to prevent interference between the conductive patterns 310 disposed apart from each other in the third direction (the Z direction).

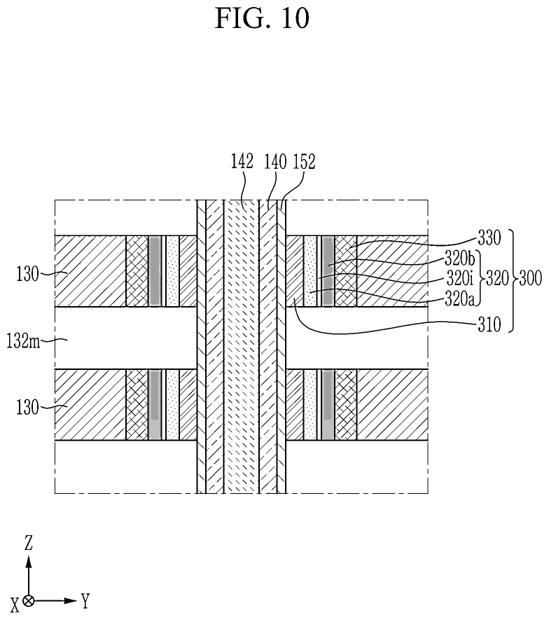

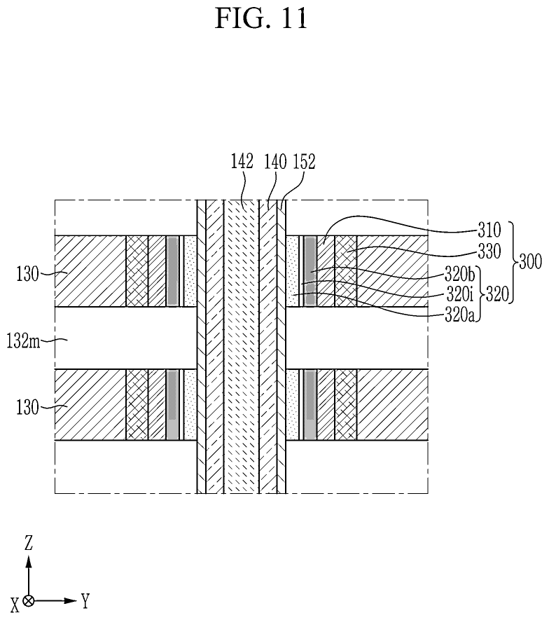

In some embodiments, the drawings illustrate that the ferroelectric pattern 320 includes a single layer, but the present disclosure is not limited thereto. The ferroelectric pattern 320 may include multiple layers. A description of this will be provided later with reference to FIG. 10 and FIG. 11.

The anti-ferroelectric pattern 330 may be disposed on a side surface of the ferroelectric pattern 320. For example, the anti-ferroelectric pattern 330 may be disposed on the exterior side surface 320_S2 of the ferroelectric pattern 320. The anti-ferroelectric pattern 330 may at least partially surround the ferroelectric pattern 320. The anti-ferroelectric pattern 330 may be disposed between the plurality of gate electrodes 130 and the channel layer 140. As an example, the anti-ferroelectric pattern 330 may be disposed between the ferroelectric pattern 320 and the plurality of gate electrodes 130. The anti-ferroelectric pattern 330 may be in contact with the side surface of the ferroelectric pattern 320 and side surfaces of the plurality of gate electrodes 130, respectively.

In some embodiments, and as shown in FIG. 6, the anti-ferroelectric pattern 330 may extend along a circumferential direction or a circumference of the channel structure CH. For example, the anti-ferroelectric pattern 330 may have an annular shape on a plane, and may at least partially surround the ferroelectric pattern 320. In other words, the anti-ferroelectric pattern 330 may extend along the circumferential direction or a circumference of the channel structure CH to surround the exterior side surface 320_S2 of the ferroelectric pattern 320. That is, the anti-ferroelectric pattern 330 may cover or overlap the side surface of the ferroelectric pattern 320 along the circumferential direction or a circumference of the channel structure CH.

Additionally, a plurality of anti-ferroelectric patterns 330 may be provided to be spaced apart from each other at a predetermined interval in the third direction (the Z direction). In other words, the plurality of anti-ferroelectric patterns 330 may be disposed apart from each other in the third direction (the Z direction). Each of the plurality of anti-ferroelectric patterns 330 disposed apart from each other in the third direction (the Z direction) may at least partially surround the ferroelectric pattern 320. Specifically, the plurality of anti-ferroelectric patterns 330 may be disposed between the plurality of gate electrodes 130 and the ferroelectric pattern 320, and may not be disposed between the plurality of interlayer insulating layers 132m and the channel insulating layer 152. Therefore, the anti-ferroelectric pattern 330 may be disposed between the plurality of gate electrodes 130 and the channel layer 140, and may not be disposed between the plurality of interlayer insulating layers 132m and the channel layer 140. In other words, the anti-ferroelectric pattern 330 may overlap the plurality of gate electrodes 130 in a radius direction of the channel structure CH, and may not overlap the plurality of interlayer insulating layers 132m in the radius direction of the channel structure CH. Additionally, the anti-ferroelectric pattern 330 may overlap the ferroelectric pattern 320 and the conductive pattern 310 in the radius direction of the channel structure CH.

In some embodiments, an upper surface of the anti-ferroelectric pattern 330 may be disposed at substantially the same level as those of an upper surface of the ferroelectric pattern 320 and an upper surface of the conductive pattern 310. That is, the upper surface of the anti-ferroelectric pattern 330 may be aligned with an upper surface of the gate electrode 130 adjacent to the anti-ferroelectric pattern 330. A distance from the upper surface of the anti-ferroelectric pattern 330 to the upper surface of the ferroelectric pattern 320, a distance from the upper surface of the anti-ferroelectric pattern 330 to the upper surface of the conductive pattern 310, and a distance from the upper surface of the anti-ferroelectric pattern 330 to an upper surface of the second substrate 110 may be substantially the same. Additionally, a lower surface of the anti-ferroelectric pattern 330 may be disposed at substantially the same level as those of a lower surface of the ferroelectric pattern 320 and a lower surface of the conductive pattern 310. That is, the lower surface of the anti-ferroelectric pattern 330 may be aligned with the lower surface of the ferroelectric pattern 320 and the lower surface of the conductive pattern 310 in the radius direction of the channel structure CH.

Accordingly, a width of the anti-ferroelectric pattern 330 in the third direction (the Z direction) may be substantially the same as a width of the ferroelectric pattern 320 in the third direction (the Z direction). Additionally, the width of the anti-ferroelectric pattern 330 in the third direction (the Z direction) may be substantially the same as a width of the conductive pattern 310 in the third direction (the Z direction). However, the present disclosure is not limited thereto, and the width of the anti-ferroelectric pattern 330 in the third direction (the Z direction) may be smaller than the width of the conductive pattern 310 in the third direction (the Z direction). A description of this will be provided later with reference to FIG. 8.

Additionally, the upper surface of the anti-ferroelectric pattern 330 may be disposed at substantially the same level as that of the upper surface of the gate electrode 130 adjacent to the anti-ferroelectric pattern 330. That is, a distance from the upper surface of the anti-ferroelectric pattern 330 to the upper surface of the gate electrode 130 adjacent to the anti-ferroelectric pattern 330 and a distance from the upper surface of the anti-ferroelectric pattern 330 to the upper surface of the second substrate 110 may be substantially the same. Additionally, the lower surface of the anti-ferroelectric pattern 330 may be disposed at substantially the same level as that of a lower surface of the gate electrode 130 adjacent to the anti-ferroelectric pattern 330. Here, the gate electrode 130 adjacent to the anti-ferroelectric pattern 330 may mean the gate electrode 130 that overlaps the anti-ferroelectric pattern 330 in the radius direction of the channel structure CH among the plurality of gate electrodes 130. Accordingly, the width of the anti-ferroelectric pattern 330 in the third direction (the Z direction) may be substantially the same as widths of the plurality of gate electrodes 130 in the third direction (the Z direction). This may be due to a characteristic of a process in which the anti-ferroelectric pattern 330 is formed within the space where the portions of the plurality of sacrificial insulating layers 130s of FIG. 15 exposed by the first channel hole CT1 of FIG. 15 are removed.

In some embodiments, a third thickness T3 in a radius direction of the channel structure CH of the anti-ferroelectric pattern 330 may be less than the second thickness T2 in the radius direction of the channel structure CH of the ferroelectric pattern 320. Here, and as shown in FIG. 5, the third thickness T3 in the radius direction of the channel structure CH of the anti-ferroelectric pattern 330 may be substantially the same as a thickness of the anti-ferroelectric pattern 330 in the second direction (the Y direction) on the cross-section including the second direction (the Y direction) and the third direction (the Z direction). That is, in some embodiments, the thickness of the anti-ferroelectric pattern 330 in the second direction (the Y direction) may be less than a thickness of the ferroelectric pattern 320 in the second direction (the Y direction).

The anti-ferroelectric pattern 330 may include an anti-ferroelectricity material (or an anti-ferroelectric material). For example, the anti-ferroelectric pattern 330 may include an Hf compound or a Zr compound with an anti-ferroelectric characteristic. As an example, the anti-ferroelectric pattern 330 may include HfZrO, but the present disclosure is not limited thereto.

In some embodiments, if the anti-ferroelectric pattern 330 includes an anti-ferroelectricity material, and the anti-ferroelectric pattern 330 may generate a predetermined remnant polarization according to a voltage applied between the plurality of gate electrodes 130 and the channel layer 140. For example, if an external electric field (e.g., an electric field generated by a voltage difference applied between the plurality of gate electrodes 130 and the channel layer 140) is applied to the anti-ferroelectric pattern 330, the remnant polarization may be generated within the anti-ferroelectric pattern 330. In this case, a dielectric constant of the anti-ferroelectric pattern 330 may increase. In one variation, when the external electric field (e.g., the electric field generated by the voltage difference applied between the plurality of gate electrodes 130 and the channel layer 140) is not applied to the anti-ferroelectric pattern 330, the remnant polarization generated within the anti-ferroelectric pattern 330 may be close to zero. In this case, the dielectric constant of the anti-ferroelectric pattern 330 may decrease.

Accordingly, if a voltage is applied to the plurality of gate electrodes 130 of the semiconductor device 10 according to some embodiments, the dielectric constant of the anti-ferroelectric pattern 330 may increase so that an electric charge is concentrated within the anti-ferroelectric pattern 330. Thus, the remnant polarization may be easily generated within the ferroelectric pattern 320. In other words, an operating voltage characteristic of the ferroelectric pattern 320 may be improved.

In addition, each of the anti-ferroelectric patterns 330 disposed apart from each other in the third direction (the Z direction) of the semiconductor device 10 according to some embodiments may at least partially surround the ferroelectric patterns 320 disposed apart from each other in the third direction (the Z direction) so that interference between the anti-ferroelectric patterns 330 is prevented.

Referring again to FIG. 1 and FIG. 2, the channel pad 144 may be disposed on the channel layer 140. The channel pad 144 may be disposed to cover or overlap an upper surface of the core insulating layer 142 and to be electrically connected to the channel layer 140. The side surface of the channel pad 144 may be in contact with the channel insulating layer 152. The channel pad 144 may include a conductive material (for example, polysilicon doped with an impurity). However, the material of the channel pad 144 is not limited thereto, and may be variously modified.

As described above, if the gate stacking structure 120 includes the plurality of gate stacking structures 120a and 120b stacked on each other, and the channel structure CH may include a plurality of channel structures CH1 and CH2 penetrating or extending into the plurality of gate stacking structures 120a and 120b, respectively. For example, when the plurality of gate stacking structures 120 includes the first gate stacking structure 120a and the second gate stacking structure 120b, the plurality of channel structures CH may include the first channel structure CH1 extending through the first gate stacking structure 120a and the second channel structure CH2 extending through the second gate stacking structure 120b.

The first channel structure CH1 and the second channel structure CH2 may have a shape connected to each other. When first channel structure CH1 and the second channel structure CH2 are viewed in a cross-section, each of the first channel structure CH1 and the second channel structure CH2 may have an inclined side surface so that a width of each of the first and second channel structures becomes narrow as the each of the first and second structures is close to or approaches the second substrate 110 according to an aspect ratio. As shown in FIG. 3, a bent portion may be provided due to a difference in widths of each of the first and second channel structures at the portion where the first channel structure CH1 and the second channel structure CH2 are connected. As another example, as shown in FIG. 4, the first channel structure CH1 and the second channel structure CH2 may have an inclined side surface continuously connected without a bent portion. However, shapes of the first channel structure CH1 and the second channel structure CH2 are not limited thereto, and may be variously modified.

FIG. 1 and FIG. 2 illustrate that the dielectric layer 300, the channel layer 140, and the core insulating layer 142 of the first channel structure CH1 and the second channel structure CH2 have an integral structure extending from each other. After a first penetration portion for the first channel structure CH1 and a second penetration portion for the second channel structure CH2 are formed, the above-described structure may be formed by forming the dielectric layer 300, the channel layer 140, and the core insulating layer 142 throughout the first and second penetration portions. However, the present disclosure is not limited thereto. As another example, the dielectric layer 300, the channel layer 140, and the core insulating layer 142 of the first channel structure CH1 and the second channel structure CH2 may be separately formed to be electrically connected to each other. For example, after the first penetration portion for the first channel structure CH1 is formed, the dielectric layer 300, the channel layer 140, and the core insulating layer 142 may be formed at the first penetration portion, and after the second penetration portion for the second channel structure CH2 is formed, the gate dielectric layer 300, the channel layer 140, and the core insulating layer 142 may be formed at the second penetration portion. Various other changes are possible.

In some embodiments, the channel pad 144 may be provided on the channel structure CH (e.g., the second channel structure CH2) provided in the gate stacking structure (e.g., the second gate stacking structure 120b) disposed at upper portions of the plurality of gate stacking structures 120. Alternatively, channel pads 144 may be respectively provided on the first channel structure CH1 and the second channel structure CH2. In this case, the channel pad 144 of the first channel structure CH1 may be connected to the channel layer 140 of the second channel structure CH2.

The semiconductor device 10 according to some embodiments may further include a separation structure 146.

The separation structure 146 may extend in the third direction (the Z direction) to penetrate or extend into the gate stacking structure 120. Accordingly, the gate stacking structure 120 may be divided into a plurality of portions on a plane by the separation structure 146.

For example, the separation structure 146 may penetrate or extend into the plurality of gate electrodes 130 and the cell insulating layer 132 to extend to an upper surface of the second substrate 110. On a plane, the separation structure 146 may extend in the first direction (the X direction), and a plurality of separation structures 146 may be provided to be spaced apart from each other at a predetermined interval in the second direction (the Y direction) crossing the first direction (the X direction). Accordingly, on a plane, the plurality of gate stacking structures 120 may extend in the first direction (the X direction), and may be spaced apart from each other at a predetermined interval in the second direction (the Y direction). The gate stacking structure 120 divided by the separation structure 146 may constitute one memory cell block. However, the present disclosure is not limited thereto, and a range of the memory cell block is not limited thereto.

For example, when the separation structure 146 is viewed in a cross-section, the separation structure 146 may have an inclined side surface so that a width of the separation structure 146 is reduced while the separation structure faces the second substrate 110 due to a high aspect ratio. However, the present disclosure is not limited thereto, and a side surface of the separation structure 146 may be perpendicular to the second substrate 110. FIG. 2 illustrates that the separation structure 146 has a continuous inclined side surface at the first gate stacking structure 120a and the second gate stacking structure 120b and does not include a bent portion when the separation structure 146 is viewed in a cross-section. However, the present disclosure is not limited thereto, and the separation structure 146 may include the bent portion at a boundary portion between the first gate stacking structure 120a and the second gate stacking structure 120b.

The separating structure 146 may be filled with or include various insulating materials. For example, the separating structure 146 may include an insulating material such as silicon oxide, silicon nitride, or silicon oxynitride. However, the present disclosure is not limited thereto, and a structure, a shape, a material, or the like of the separation structure 146 may be variously modified.

The semiconductor device according to some embodiments may further include an upper separation pattern 148.

The upper separation pattern 148 may be disposed at an upper portion of the gate stacking structure 120. On a plane, the upper separation pattern 148 may extend in the first direction (the X direction), and a plurality of upper separation patterns 148 may be provided to be spaced apart from each other at a predetermined interval in the second direction (the Y direction).

The upper separation pattern 148 may be formed by penetrating or extending into one or a plurality of gate electrodes 130 including the upper gate electrode 130U disposed between the separation structures 146. For example, the upper separation pattern 148 may separate two gate electrodes 130 from each other in the second direction (the Y direction). However, the number of the plurality of gate electrodes 130 separated by the upper separation pattern 148 is not limited thereto, and may be variously modified.

The upper separation pattern 148 may have a shape filled with or including an insulating material. For example, the upper separation pattern may include an insulating material such as silicon oxide (SiO₂), silicon nitride (SiN), or silicon oxynitride (SiON). However, the present disclosure is not limited thereto, and a structure, a shape, a material, or the like of the upper separation pattern 148 may be variously modified.

The contact region 104 and the second wiring portion 180 may be provided to connect the gate stacking structure 120 and the channel structure CH provided in the cell array region 102 to the circuit region 200 or an external circuit.

Here, the second wiring portion 180 may include a member electrically connecting the plurality of gate electrodes 130, the channel structure CH, and/or the second substrate 110 to the circuit region 200 or the external circuit. For example, the second wiring portion 180 may include a bit line 182, the gate contact portion 184, a source contact portion 186, a through plug 188, a contact via 180a connected to each of the bit line 182, the gate contact portion 184, the source contact portion 186, and the through plug 188, and a connection wire 190 connecting the bit line 182, the gate contact portion 184, the source contact portion 186, and the through plug 188.

The bit line 182 may be disposed above the cell insulating layer 132 of the gate stacking structure 120 formed in the cell array region 102. The bit line 182 may extend in the second direction (the Y direction). The bit line 182 may be electrically connected to the channel structure CH (e.g., the channel pad 144) through the contact via 180a (e.g., a bit line contact via).

The contact region 104 may be disposed to at least partially surround the cell array region 102. A portion of the second wiring portion 180 may be disposed at the contact region 104. The contact region 104 may include the gate stacking structure 120 disposed above the second substrate 110 and the gate contact portion 184 for connecting the plurality of gate electrodes 130 of the cell array region 102 to the circuit region 200 or an external circuit.

More specifically, the plurality of gate electrodes 130 may be disposed to extend in the second direction (the Y direction) in the contact region 104, and extension lengths of the plurality of gate electrodes 130 in the contact region 104 may become sequentially smaller as the plurality of gate electrodes move away from the second substrate 110. For example, the plurality of gate electrodes 130 may be disposed at the contact region 104 with a stair shape. In this case, the plurality of gate electrodes 130 may have a stair shape in one direction or in plurality of directions. A plurality of gate contact portions 184 may penetrate or extend into the cell insulating layer 132 in the contact region 104 to be electrically connected to the plurality of gate electrodes 130 extending to the contact region 104, respectively.

Additionally, in the contact region 104, the source contact portion 186 may penetrate or extend into the cell insulating layer 132 to be electrically connected to the second substrate 110. For example, the source contact portion 186 may be electrically connected to the second substrate 110 by penetrating or extending into the second horizontal conductive layer 114 and the horizontal insulating layer 116.

The through plug 188 may penetrate or extend into the gate stacking structure 120 or may be disposed outside the gate stacking structure 120 to be electrically connected to the first wiring portion 230 of the circuit region 200. However, the present disclosure is not limited thereto, and the through plug 188 may penetrate or extend into the gate stacking structure 120 to be electrically connected to the first wiring portion 230 of the circuit region 200.

The connection wire 190 may be disposed at the cell array region 102 and/or the contact region 104. The bit line 182, the gate contact portion 184, the source contact portion 186, and/or the through plug 188 may be electrically connected to the connection wire 190. For example, the gate contact portion 184, the source contact portion 186, and/or the through plug 188 may be connected to the connection wire 190 through the contact via 180a.

FIG. 1 illustrates that the connection wire 190 is provided as a single layer disposed above or on the same plane as that of the bit line 182 and a second insulating layer 192 is disposed at a portion other than the second wiring portion 180. However, this is only briefly shown for convenience. Therefore, in order for the connection wire 190 to make electrical connection with the bit line 182, the gate contact portion 184, the source contact portion 186, and/or the through plug 188, the connection wire 190 may include a plurality of wiring layers, and may further include a contact via.

Thus, the bit line 182, the plurality of gate electrodes 130, and/or the second substrate 110 connected to the channel structure CH may be electrically connected to the circuit element 220 of the circuit region 200 by the second wiring portion 180 and the first wiring portion 230.

FIG. 1 illustrates that each of the gate contact portion 184, the source contact portion 186, and/or the through plug 188 have an inclined side surface so that a width of each of the gate contact portion 184, the source contact portion 186, and/or the through plug 188 becomes narrow as each of the gate contact portion 184, the source contact portion 186, and/or the through plug 188 is close to the second substrate 110 according to an aspect ratio when each of the gate contact portion 184, the source contact portion 186, and/or the through plug 188 is viewed in a cross-section and the bent portion is provided at the boundary portion between the first gate stacking structure 120a and the second gate stacking structure 120b. However, the present disclosure is not limited thereto. For example, it is also possible that the gate contact portion 184, the source contact portion 186, and/or the through plug 188 do not have the bent portion between the first gate stacking structure 120a and the second gate stacking structure 120b. Various other changes are possible.

The conductive pattern 310 of the semiconductor device 10 according to some embodiments may include a conductive material. Thus, when a voltage is applied to the plurality of gate electrodes 130, an electric field within the conductive pattern 310 may be distributed with a uniform density. Accordingly, the electric field having the uniform density may be distributed at a portion of the ferroelectric pattern 320 that overlaps the conductive pattern 310 in the radius direction of the channel structure CH, and a remnant polarization may be uniformly generated within the ferroelectric pattern 320. Therefore, the reliability of the semiconductor device 10 may be improved.

Additionally, when a voltage is applied to the plurality of gate electrodes 130 of the semiconductor device 10 according to some embodiments, a dielectric constant of the anti-ferroelectric pattern 330 may increase so that an electric charge is concentrated within the anti-ferroelectric pattern 330. Accordingly, the remnant polarization may be easily generated within the ferroelectric pattern 320. In other words, an operating voltage characteristic of the ferroelectric pattern 320 may be improved.

Additionally, the plurality of dielectric layers 300 according to some embodiments may be disposed apart from each other along the third direction (the Z direction). Specifically, the conductive pattern 310, the ferroelectric pattern 320, and the anti-ferroelectric pattern 330 may be disposed only between the plurality of gate electrodes 130 and the ferroelectric pattern 320. Accordingly, when a voltage is applied to the gate electrode 130, an electric field may be concentrated on the dielectric layer 300 disposed at one side of the gate electrode 130 to which the voltage is applied. Therefore, it is possible to prevent interference between the plurality of dielectric layers 300 disposed apart from each other in the third direction (the Z direction).

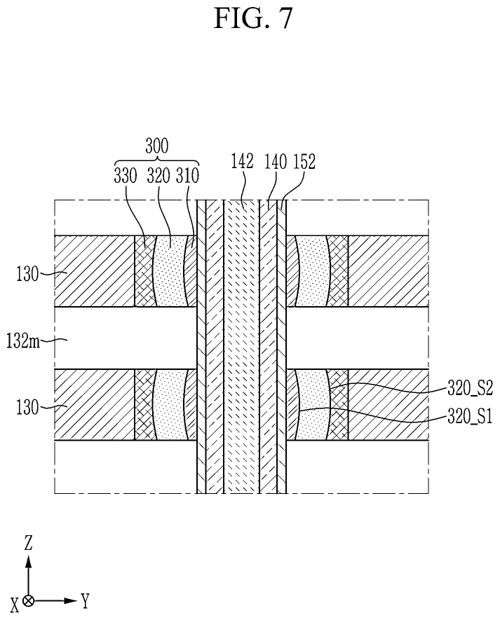

Hereinafter, a semiconductor device according to some embodiments will be described with further reference to FIGS. 7 to 11. A detailed description of a portion identical to or substantially similar to the portion already described will be omitted, and only another portion will be described in detail.

FIG. 7 is a cross-sectional view showing a semiconductor device according to some embodiments and corresponding to the region S1 of FIG. 2.

The semiconductor device shown in FIG. 7 is similar to the semiconductor device according to the embodiments shown in FIGS. 1 to 6, so that a description thereof will be omitted and a difference between the semiconductor device of FIG. 7 and the semiconductor device of FIGS. 1 to 6 will be mainly described. In addition, the same reference numeral is used for a component that is the same as that of the previous embodiments. In the present embodiments, shapes of a side surface of the conductive pattern 310, a side surface of the ferroelectric pattern 320, and a side surface of the anti-ferroelectric pattern 330 may be different from the previous embodiments, and will be described below.

Referring to FIG. 1 and FIG. 7, the cell region 100 of the semiconductor device 10 according to some embodiments may include the second substrate 110, the gate stacking structure 120 disposed on the second substrate 110, and the channel structure CH penetrating or extending into the gate stacking structure 120 and including the channel layer 140 and the plurality of dielectric layers 300.

Additionally, each of the plurality of dielectric layers 300 of the semiconductor device 10 according to some embodiments may include the conductive pattern 310, the ferroelectric pattern 320, and the anti-ferroelectric pattern 330 sequentially stacked on the exterior side surface of the channel insulating layer 152.

In the previous embodiments, the side surface of the conductive pattern 310, the side surface of the ferroelectric pattern 320, and the side surface of the anti-ferroelectric pattern 330 may extend straight in the third direction (the Z direction).

Referring to FIG. 7, the exterior side surface of the conductive pattern 310 according to some embodiments may have a convex shape from the exterior side surface of the channel insulating layer 152. Accordingly, a thickness of the conductive pattern 310 along the radius direction of the channel structure CH may increase and then decrease as the conductive pattern 310 moves away from an upper surface of the second substrate 110.

Additionally, the interior side surface 320_S1 of the ferroelectric pattern 320 may have a shape that complements or accommodates the exterior side surface of the conductive pattern 310. That is, the interior side surface of the ferroelectric pattern 320 may have a concave shape toward the plurality of gate electrodes 130. Additionally, the exterior side surface 320_S2 of the ferroelectric pattern 320 may have a convex shape from the exterior side surface of the channel insulating layer 152. A thickness of the ferroelectric pattern 320 along the radius direction of the channel structure CH may be constant as the ferroelectric pattern 320 moves away from the upper surface of the second substrate 110, but the present disclosure is not limited thereto. An interior side surface of the anti-ferroelectric pattern 330 may have a shape that complements or accommodates the exterior side surface 320_S2 of the ferroelectric pattern 320. That is, the interior side surface of the anti-ferroelectric pattern 330 may have a concave shape toward the plurality of gate electrodes 130.

FIG. 8 is a cross-sectional view showing a semiconductor device according to some embodiments and corresponding to the region S1 of FIG. 2.

The semiconductor device shown in FIG. 8 is similar to the semiconductor device according to some embodiments shown in FIGS. 1 to 6, so that a description thereof will be omitted and a difference between the semiconductor device of FIG. 8 and the semiconductor device of FIGS. 1 to 6 will be mainly described. In addition, the same reference numeral is used for a component that is the same as that of the previous embodiments. In the present embodiments, a shape of the conductive pattern 310 may be different from the previous embodiments, and will be described below.

Referring to FIG. 1 and FIG. 8, the cell region 100 of the semiconductor device 10 according to some embodiments may include the second substrate 110, the gate stacking structure 120 disposed on the second substrate 110, and the channel structure CH penetrating or extending into the gate stacking structure 120 and including the channel layer 140 and the plurality of dielectric layers 300.

Additionally, each of the plurality of dielectric layers 300 of the semiconductor device 10 according to some embodiments may include the conductive pattern 310, the ferroelectric pattern 320, and the anti-ferroelectric pattern 330 sequentially stacked on the exterior side surface of the channel insulating layer 152.

In the previous embodiments, the width of the conductive pattern 310 along the third direction (the Z direction) may be substantially the same as the width of the ferroelectric pattern 320 along the third direction (the Z direction).

Referring to FIG. 8, a first width D1 of the conductive pattern 310 according to some embodiments in the third direction (the Z direction) may be larger than a second width D2 of the ferroelectric pattern 320 in the third direction (the Z direction).

In some embodiments, the upper surface of the conductive pattern 310 may be disposed at a higher level than the upper surface of the ferroelectric pattern 320 and the upper surface of the anti-ferroelectric pattern 330. That is, the upper surface of the conductive pattern 310 may be disposed farther from the upper surface of the second substrate 110 than the upper surface of the ferroelectric pattern 320 and the upper surface of the anti-ferroelectric pattern 330. Additionally, the lower surface of the conductive pattern 310 may be disposed at a lower level than the lower surface of the ferroelectric pattern 320 and the lower surface of the anti-ferroelectric pattern 330. That is, the lower surface of the conductive pattern 310 may be disposed closer to the upper surface of the second substrate 110 than the lower surface of the ferroelectric pattern 320 and the lower surface of the anti-ferroelectric pattern 330. Accordingly, the first width D1 of the conductive pattern 310 in the third direction (the Z direction) may be larger than the second width D2 of the ferroelectric pattern 320 in the third direction (the Z direction). However, even in this case, the plurality of conductive patterns 310 may be provided to be spaced apart from each other at a predetermined interval along the third direction (the Z direction).

FIG. 9 is a cross-sectional view showing a semiconductor device according to some embodiments and corresponding to the region S1 of FIG. 2.

The semiconductor device shown in FIG. 9 is similar to the semiconductor device according to some embodiments shown in FIGS. 1 to 6, so that a description thereof will be omitted and a difference between the semiconductor device of FIG. 9 and the semiconductor device of FIGS. 1 to 6 will be mainly described. In addition, the same reference numeral is used for a component that is the same as that of the previous embodiments. In the present embodiments, a position of the conductive pattern 310 may be different from the previous embodiments, and will be described below.

Referring to FIG. 1 and FIG. 9, the cell region 100 of the semiconductor device 10 according to some embodiments may include the second substrate 110, the gate stacking structure 120 disposed on the second substrate 110, and the channel structure CH penetrating or extending into the gate stacking structure 120 and including the channel layer 140 and the plurality of dielectric layers 300.

Additionally, each of the plurality of dielectric layers 300 of the semiconductor device 10 according to some embodiments may include the conductive pattern 310, the ferroelectric pattern 320, and the anti-ferroelectric pattern 330.

In the preceding embodiment, the conductive pattern 310 may be disposed on the exterior side surface of the channel insulating layer 152. The conductive pattern 310 may be in contact with the exterior side surface of the channel insulating layer 152. Additionally, the ferroelectric pattern 320 may be disposed between the conductive pattern 310 and the anti-ferroelectric pattern 330.

Referring to FIG. 9, the ferroelectric pattern 320 according to some embodiments may be disposed on the exterior side surface of the channel insulating layer 152. The ferroelectric pattern 320 may surround at least a portion of the channel insulating layer 152. The ferroelectric pattern 320 may be disposed between the conductive pattern 310 and the channel insulating layer. The ferroelectric pattern 320 may be in contact with the conductive pattern 310 and the channel insulating layer 152.

In some embodiments, the plurality of ferroelectric patterns 320 may be provided to be spaced apart from each other at a predetermined interval in the third direction (the Z direction). In other words, the plurality of ferroelectric patterns 320 may be disposed apart from each other in the third direction (the Z direction). The ferroelectric pattern 320 may be disposed between the plurality of gate electrodes 130 and the channel layer 140, and may not be disposed between the plurality of interlayer insulating layers 132m and the channel layer 140. That is, the ferroelectric pattern 320 may overlap the plurality of gate electrodes 130 in the radius direction of the channel structure CH (e.g., the Y direction), and may not overlap the plurality of interlayer insulating layers 132m in the radius direction of the channel structure CH. However, the present disclosure is not limited thereto, and the ferroelectric pattern 320 may extend in the third direction (e.g., the Z direction) to surround the entire channel insulating layer 152.

The conductive pattern 310 may be disposed on the exterior side surface of the ferroelectric pattern 320. The conductive pattern 310 may at least partially surround the ferroelectric pattern 320. The conductive pattern 310 may be disposed between the ferroelectric pattern 320 and the anti-ferroelectric pattern 330. The conductive pattern 310 may be in contact with the ferroelectric pattern 320 and the anti-ferroelectric pattern 330. Because the remaining description of the conductive pattern 310 is substantially the same as the description of the conductive pattern 310 of the embodiments of FIGS. 1 to 6, a description thereof will be omitted.

The anti-ferroelectric pattern 330 may be disposed on the exterior side surface of the conductive pattern 310. The anti-ferroelectric pattern 330 may at least partially surround the conductive pattern 310. The anti-ferroelectric pattern 330 may be disposed between the conductive pattern 310 and the plurality of gate electrodes 130. The anti-ferroelectric pattern 330 may be in contact with the conductive pattern 310 and the plurality of gate electrodes 130. Because the remaining description of the anti-ferroelectric pattern 330 is substantially the same as the description of the anti-ferroelectric pattern 330 of the embodiments of FIGS. 1 to 6, a description thereof will be omitted.

The conductive pattern 310 of the semiconductor device 10 according to some embodiments may include a conductive material. Thus, when a voltage is applied to the plurality of gate electrodes 130, an electric field within the conductive pattern 310 may be distributed with a uniform density. Accordingly, the electric field having the uniform density may be distributed at a portion of the ferroelectric pattern 320 that overlaps the conductive pattern 310 in the radius direction of the channel structure CH, and a remnant polarization may be uniformly generated within the ferroelectric pattern 320. Therefore, the reliability of the semiconductor device 10 may be improved.

Additionally, when a voltage is applied to the plurality of gate electrodes 130 of the semiconductor device 10 according to some embodiments, a dielectric constant of the anti-ferroelectric pattern 330 may increase so that an electric charge is concentrated within the anti-ferroelectric pattern 330. Accordingly, the remnant polarization may be easily generated within the ferroelectric pattern 320. In other words, an operating voltage characteristic of the ferroelectric pattern 320 may be improved.

Additionally, the plurality of dielectric layers 300 according to some embodiments may be disposed apart from each other in the third direction (the Z direction). Specifically, the conductive pattern 310, the ferroelectric pattern 320, and the anti-ferroelectric pattern 330 may be disposed between the plurality of gate electrodes 130 and the ferroelectric pattern 320, and may not be disposed between the plurality of interlayer insulating layers 132m and the ferroelectric pattern 320. Accordingly, when a voltage is applied to the gate electrode 130, an electric field may be concentrated on the dielectric layer 300 disposed at one side of the gate electrode 130 to which the voltage is applied. Therefore, it is possible to prevent interference between the plurality of dielectric layers 300 disposed apart from each other in the third direction (the Z direction).

FIG. 10 and FIG. 11 are cross-sectional views showing a semiconductor device according to some embodiments and corresponding to the region S1 of FIG. 2.

The semiconductor device according to some embodiments shown in FIG. 10 and FIG. 11 is similar to the semiconductor device according to some embodiments shown in FIGS. 1 to 6, so that a description thereof will be omitted and a difference between the semiconductor device of FIG. 10 and FIG. 11 and the semiconductor device of FIGS. 1 to 6 will be mainly described. In addition, the same reference numeral is used for a component that is the same as that of the previous embodiments. The present embodiments may be different from the previous embodiments in that the ferroelectric pattern 320 includes multiple layers, and will be described below.

Referring to FIG. 1, FIG. 10, and FIG. 11, the cell region 100 of the semiconductor device 10 according to some embodiments may include the second substrate 110, the gate stacking structure 120 disposed on the second substrate 110, and the channel structure CH penetrating or extending into the gate stacking structure 120 and including the channel layer 140 and the plurality of dielectric layers 300.

Additionally, each of the plurality of dielectric layers 300 of the semiconductor device 10 according to some embodiments may include the conductive pattern 310, the ferroelectric pattern 320, and the anti-ferroelectric pattern 330 sequentially stacked on the exterior side surface of the channel insulating layer 152.

Referring to FIG. 10 and FIG. 11, the ferroelectric pattern 320 of the semiconductor device 10 according to some embodiments may include the multiple layers. For example, the ferroelectric pattern 320 may include first and second ferroelectric patterns 320a and 320b. Additionally, the ferroelectric pattern 320 may include an interface insertion film 320i disposed between the first and second ferroelectric patterns 320a and 320b.

In some embodiments, the first and second ferroelectric patterns 320a and 320b may be disposed between the plurality of gate electrodes 130 and the channel layer 140. For example, as shown in FIG. 10, the first and second ferroelectric patterns 320a and 320b may be disposed between the conductive pattern 310 and the anti-ferroelectric pattern 330. However, the present disclosure is not limited thereto, and as shown in FIG. 11, the first and second ferroelectric patterns 320a and 320b may be disposed between the channel insulating layer 152 and the conductive pattern 310.

Specifically, referring to FIG. 10, the first and second ferroelectric patterns 320a and 320b may sequentially and at least partially surround the conductive pattern 310. That is, the first ferroelectric pattern 320a may surround the conductive pattern 310. The second ferroelectric pattern 320b may surround the first ferroelectric pattern 320a. The first and second ferroelectric patterns 320a and 320b may have an annular shape on a plane.

In the embodiment of FIG. 10, the plurality of ferroelectric patterns 320 may be provided to be spaced apart from each other at a predetermined interval in the third direction (the Z direction). In other words, the plurality of ferroelectric patterns 320 may be disposed apart from each other in the third direction (the Z direction). The ferroelectric pattern 320 may be disposed between the plurality of gate electrodes 130 and the channel layer 140, and may not be disposed between the plurality of interlayer insulating layers 132m and the channel layer 140. That is, the ferroelectric pattern 320 may overlap the plurality of gate electrodes 130 in the radius direction of the channel structure CH, and may not overlap the plurality of interlayer insulating layers 132m in the radius direction of the channel structure CH.

Referring to FIG. 11, the first and second ferroelectric patterns 320a and 320b may sequentially and at least partially surround the channel insulating layer 152. That is, the first ferroelectric pattern 320a may surround the channel insulating layer 152. The second ferroelectric pattern 320b may surround the first ferroelectric pattern 320a. The first and second ferroelectric patterns 320a and 320b may have an annular shape on a plane.

In some embodiments, the plurality of ferroelectric patterns 320 may be provided to be spaced apart from each other at a predetermined interval in the third direction (the Z direction). In other words, the plurality of ferroelectric patterns 320 may be disposed apart from each other in the third direction (the Z direction). The ferroelectric pattern 320 may be disposed between the plurality of gate electrodes 130 and the channel layer 140, and may not be disposed between the plurality of interlayer insulating layers 132m and the channel layer 140. That is, the ferroelectric pattern 320 may overlap the plurality of gate electrodes 130 in the radius direction of the channel structure CH, and may not overlap the plurality of interlayer insulating layers 132m in the radius direction of the channel structure CH. However, the present disclosure is not limited thereto, and the ferroelectric pattern 320 may extend in the third direction (the Z direction) to surround the entire channel insulating layer 152.

In the embodiments of FIG. 10 and FIG. 11, at least one of the first and second ferroelectric patterns 320a and 320b may include a ferroelectric material. For example, the ferroelectric pattern 320 may include an Hf compound having a ferroelectric characteristic. As an example, the ferroelectric pattern 320 may include HfO₂, HfZnO, HfSiO, HfSiON, HfTaO, HfTiO, HfZrO, or a combination thereof.

The interface insertion film 320i may at least partially surround the first ferroelectric pattern 320a. The interface insertion film 320i may be disposed between the first ferroelectric pattern 320a and the second ferroelectric pattern 320b. The interface insertion film 320i may include an insulating material. For example, the interface insertion film 320i may include at least one of aluminum oxide (Al₂O₃), silicon oxide (SiO₂), and HfSiO.

In some embodiments, when the first and second ferroelectric patterns 320a and 320b and the interface insertion film 320i include HfSiO, a concentration of silicon (Si) included in the interface insertion film 320i may be higher than a concentration of silicon (Si) included in the first and second ferroelectric patterns 320a and 320b. In some embodiments, when the concentration of silicon (Si) included in the interface insertion film 320i is high, the interface insertion film 320i may function as an insulating layer between the first and second ferroelectric patterns 320a and 320b. Here, the concentration of silicon (Si) included in the interface insertion film 320i may mean a content of a silicon (Si) element included in the interface insertion film 320i.

FIG. 10 and FIG. 11 illustrate that the ferroelectric pattern 320 includes two dielectric layers, but the present disclosure is not limited thereto. For example, the ferroelectric pattern 320 may include three or more dielectric layers.

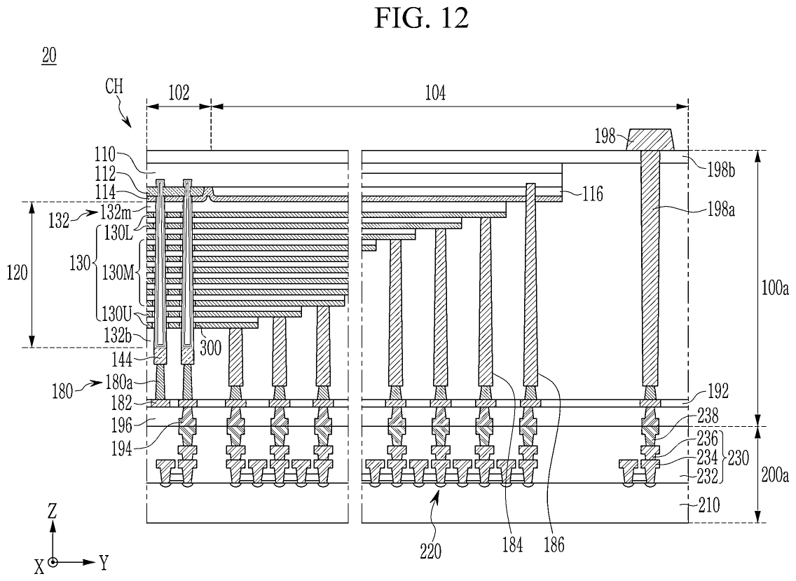

Next, a semiconductor device according to some embodiments will be described with reference to FIG. 12.

FIG. 12 is a cross-sectional view showing the semiconductor device according to some embodiments.

The embodiment shown in FIG. 12 is similar to the embodiment shown in FIGS. 1 to 11, so that a description thereof will be omitted and a difference between the embodiment of FIG. 12 and the embodiment of FIGS. 1 to 11 will be mainly described. In addition, the same reference numeral is used for a component that is the same as that of the previous embodiments.

Referring to FIG. 12, the semiconductor device 20 according to some embodiments may have a chip-to-chip (C2C) structure bonded by a wafer bonding method. That is, a lower chip including a circuit region 200a formed on the first substrate 210 may be manufactured, an upper chip including a cell region 100a formed on the second substrate 110 may be manufactured, and then the semiconductor device may be manufactured by bonding the lower chip and the upper chip.

The circuit region 200a may include the first substrate 210, the circuit element 220, and a first bonding structure (or a first junction structure) 238 at a surface facing the cell region 100a on the first wiring portion 230.

The cell region 100a may include the second substrate 110, the gate stacking structure 120, the channel structure CH, and a second bonding structure 194 at a surface facing the circuit region 200a on the second wiring portion 180.

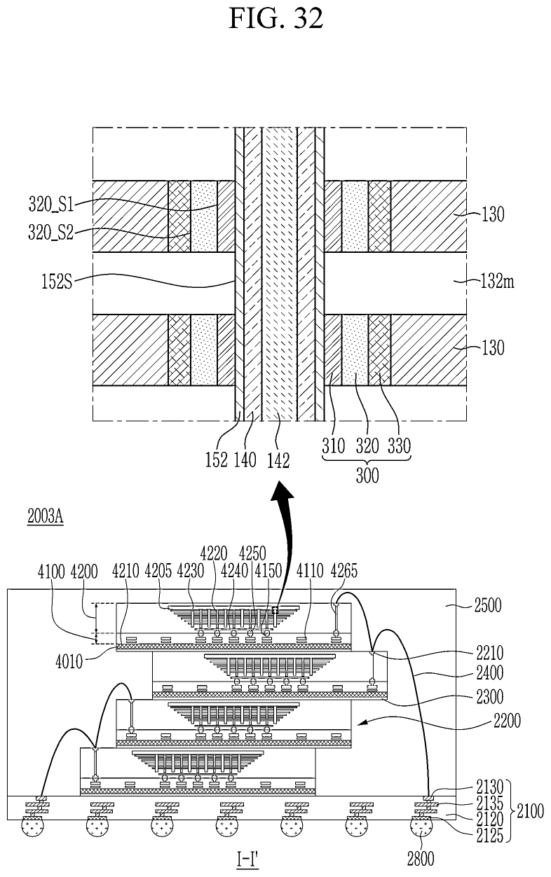

In the gate stacking structure 120, the plurality of gate electrodes 130 may include the lower gate electrode 130L, the memory cell gate electrode 130M, and the upper gate electrode 130U sequentially disposed from the second substrate 110 toward the circuit region 200a. That is, as shown in FIG. 32, the gate stacking structure 120 may be stacked below the second substrate 110 so that the gate stacked structure 120 may have a shape in which the gate stacking structure 120 shown in FIGS. 1 to 11 is disposed in a vertically inverted manner.

Accordingly, the channel pad 144 and the second wiring portion 180 disposed on the gate stacking structure 120 may be disposed adjacent to the circuit region 200a. Additionally, the second bonding structure 194 electrically connected to the second wiring portion 180 may be provided at the surface opposite the circuit region 200a. A region other than the second bonding structure 194 may be covered or overlapped by the insulating layer 196. Thus, the second wiring portion 180 and the second bonding structure 194 may be disposed in the cell region 100a to face the circuit region 200a.

For example, the second bonding structure 194 of the cell region 100a and the first bonding structure 238 of the circuit region 200a may be made of aluminum, copper, tungsten, or an alloy including aluminum, copper, and tungsten. For example, the first and second bonding structures 238 and 194 may include copper so that the cell region 100a and the circuit region 200a may be bonded (e.g., bonded directly in contact with each other) by copper-to-copper bonding.

FIG. 12 illustrates that the gate stacking structure 120 includes a single gate stacking structure, but as shown in FIG. 1, the gate stacking structure 120 may include a plurality of gate stacking structures. Except for cases described separately, the description of the gate stacking structure 120 and the channel structure CH described with reference to FIGS. 1 to 11 may be applied to FIG. 12.

The semiconductor device 20 according to some embodiments may include an input/output pad 198 and an input/output connection wire 198a electrically connected to the input/output pad. The input/output connection wire 198a may be electrically connected to a portion of the second bonding structure 194. For example, the input/output pad 198 may be disposed on an insulating film 198b covering or overlapping an outer surface of the second substrate 110. According to some embodiments, a separate input/output pad electrically connected to the circuit region 200a may be provided.

For example, the circuit region 200a and the cell region 100a may be portions corresponding to the first structure 1100F and the second structure 1100S of the semiconductor device 1100 included in the electronic system 1000 shown in FIG. 29, respectively. Alternatively, the circuit region 200a and the cell region 100a may be portions including a first structure 4100 and a second structure 4200 of the semiconductor chip 2200 shown in FIG. 31, respectively.

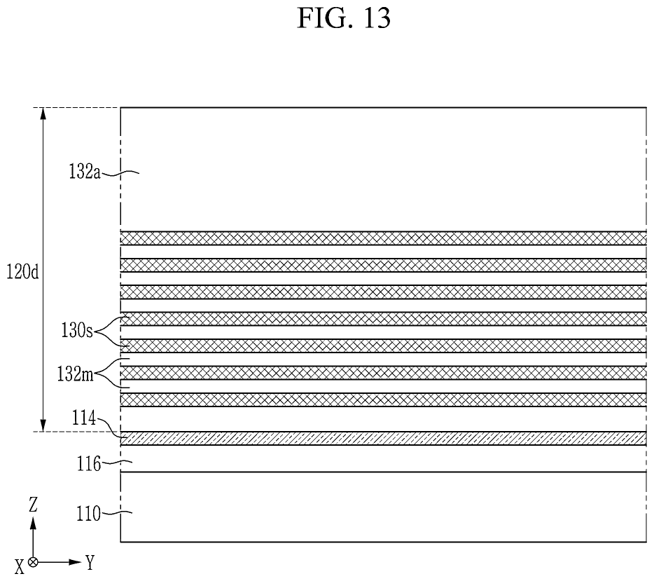

Hereinafter, a method for manufacturing the semiconductor device according to some embodiments will be described with reference to FIGS. 13 to 24.

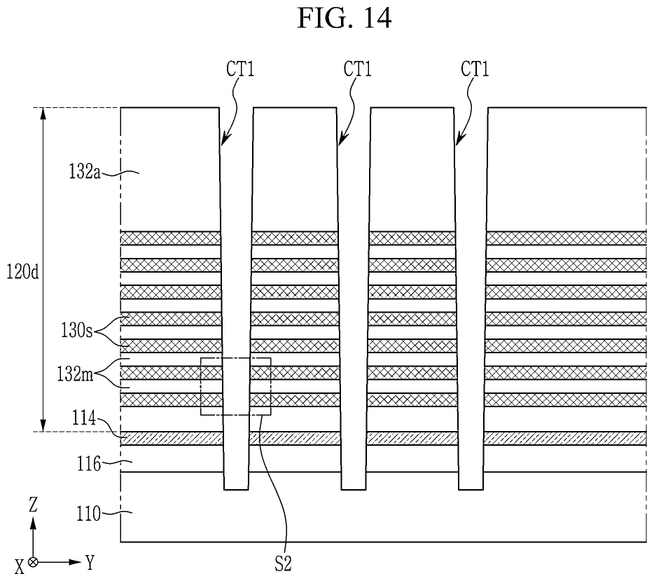

FIG. 13 and FIG. 14 are cross-sectional views of intermediate steps sequentially showing the method for manufacturing the semiconductor device according to some embodiments. FIGS. 15 to 24 are cross-sectional views sequentially showing the method for manufacturing the semiconductor device according to some embodiments and corresponding to a region S2 of FIG. 14. Here, FIGS. 13 to 24 are views of intermediate steps showing the method for manufacturing the semiconductor device according to some embodiments.

In FIG. 13 and FIG. 14, only the cell structure is shown for convenience, and a circuit region including a peripheral circuit region is omitted. Additionally, although FIG. 13 and FIG. 14 illustrate that a stacking structure 120d is formed as one stacking structure, the present disclosure is not limited thereto, and the stacking structure 120d may be formed as two or more stacking structures. Hereinafter, a method for manufacturing the plurality of dielectric layers 300 of the semiconductor device according to some embodiments will be mainly described.

Referring to FIG. 13, the horizontal insulating layer 116 and the second horizontal conductive layer 114 may be stacked on the second substrate 110, and the stacking structure 120d may be formed on the second horizontal conductive layer 114. A circuit region may be formed below the second substrate 110, and the circuit region is not shown. For example, the circuit region may be first formed, and then the second substrate 110 may be formed on the circuit region. However, the present disclosure is not limited thereto, and a structure below the second substrate 110 and the method of forming the structure below the second substrate may be variously modified.

First, the horizontal insulating layer 116 may be formed on the second substrate 110 using an insulating material. The second substrate 110 may include a semiconductor material (e.g., polysilicon). For example, the second substrate 110 may include polysilicon doped with an impurity. However, a material of the second substrate 110 is not limited thereto, and may be variously modified. For example, the second substrate 110 may include a conductive material or metal silicide.

The horizontal insulating layer 116 may be made of a single layer or multiple layers. For example, the horizontal insulating layer 116 may be formed by sequentially stacking silicon oxide, silicon nitride, and silicon oxide. At least a portion of the horizontal insulating layer 116 may be a layer that is replaced with the first horizontal conductive layer 112 of FIG. 1 in a subsequent process. That is, the horizontal insulating layer 116 may be formed to include a portion where the first horizontal conductive layer 112 of FIG. 1 will be formed. The horizontal insulating layer 116 may include a plurality of layers sequentially stacked on the second substrate 110, but the present disclosure is not limited thereto.

Subsequently, the second horizontal conductive layer 114 may be formed on the horizontal insulating layer 116. The second horizontal conductive layer 114 may be formed using a semiconductor material (e.g., polysilicon). For example, the second horizontal conductive layer 114 may include polysilicon doped with an impurity.

Next, the plurality of interlayer insulating layers 132m and the plurality of sacrificial insulating layers 130s may be alternately stacked on the second horizontal conductive layer 114 to form the stacking structure 120d. After the plurality of interlayer insulating layers 132m and the plurality of sacrificial insulating layers 130s are alternately stacked, the first upper insulating layer 132a may be formed at an uppermost portion of the plurality of interlayer insulating layers 132m and the plurality of sacrificial insulating layers 130s.

The plurality of sacrificial insulating layers 130s may include silicon oxide, silicon nitride, silicon oxynitride, a low dielectric constant material, or the like. The plurality of sacrificial insulating layers 130s may include a different material from that of the plurality of interlayer insulating layers 132m. The plurality of sacrificial insulating layers 130s may include a material having etching selectivity with respect to the plurality of interlayer insulating layers 132m. For example, the plurality of sacrificial insulating layers 130s may include at least one of silicon, silicon oxide, silicon carbide, and silicon nitride, but may be made of a different material from those of the plurality of interlayer insulating layers 132m. As an example, the plurality of interlayer insulating layers 132m may include silicon oxide, and the plurality of sacrificial insulating layers 130s may include silicon nitride. The plurality of sacrificial insulating layers 130s may be layers that are replaced with the gate electrode 130 of FIG. 1 in a subsequent process. In other words, the plurality of sacrificial insulating layers 130s may be formed to correspond to a portion where the gate electrode 130 of FIG. 1 will be formed.

Although the drawings illustrate that the stacking structure 120d is formed as one stacking structure, the present disclosure is not limited thereto, and the stacking structure 120d may include two or more stacking structures.

Referring to FIG. 14 and FIG. 15, the first channel hole CT1 may be formed by patterning the stacking structure 120d. The stacking structure 120d may be penetrated or extended into by the first channel hole CT1. In a process of patterning the stacking structure 120d, the horizontal insulating layer 116 and the second substrate 110 may be patterned together. The horizontal insulating layer 116 may be penetrated or extended into by the first channel hole CT1, and the second substrate 110 may not be penetrated or extended into. That is, a depth of the first channel hole CT1 formed in the second substrate 110 may be smaller than a thickness of the second substrate 110. Accordingly, side surfaces of the plurality of sacrificial insulating layers 130s and side surfaces of the plurality of interlayer insulating layers 132m may be exposed.

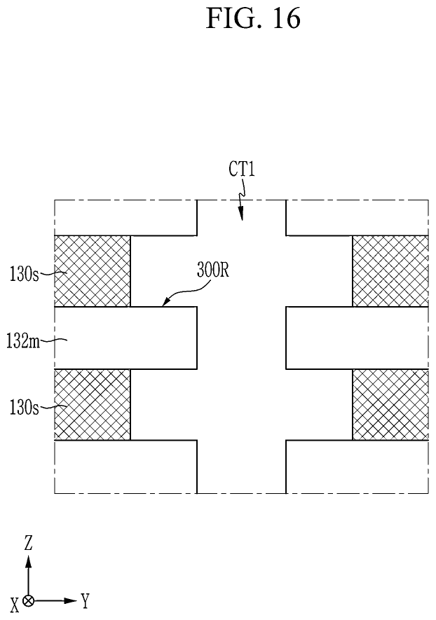

Referring to FIG. 16, a gate dielectric recess 300R may be formed by etching portions of the exposed plurality of sacrificial insulating layers 130s.

A process of etching the portions of the plurality of sacrificial insulating layers 130s may be performed using a wet etching process, but the present disclosure is not limited thereto. As described above, the plurality of sacrificial insulating layers 130s may include the material having etching selectivity with respect to the plurality of interlayer insulating layers 132m, so that the plurality of interlayer insulating layers 132m may not be etched in a process of etching the plurality of sacrificial insulating layers 130s. Accordingly, the gate dielectric recess 300R may be formed between the plurality of interlayer insulating layers 132m. In this case, a width of the gate dielectric recess 300R along the third direction (the Z direction) may be equal to widths of the plurality of sacrificial insulating layers 130s along the third direction (the Z direction).

That is, the gate dielectric recess 300R may extend from an inner sidewall of the first channel hole CT1 along a radius direction of the first channel hole CT1. For example, the gate dielectric recess 300R may extend from the inner sidewall of the first channel hole CT1 in the second direction (the Y direction). As the gate dielectric recess 300R is formed, portions of upper surfaces and portions of lower surfaces of the plurality of interlayer insulating layers 132m may be exposed.

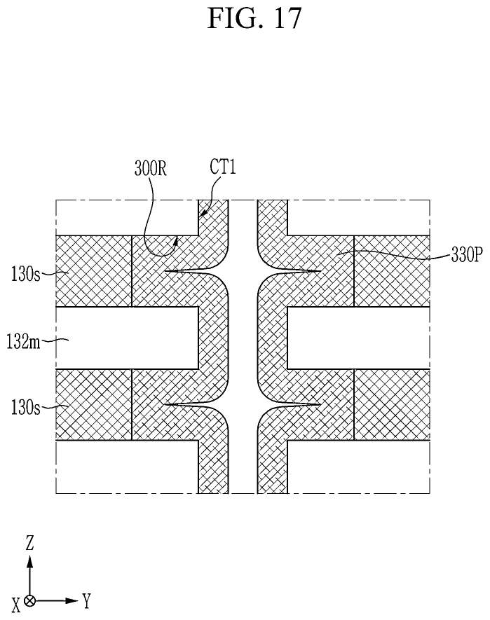

Referring to FIG. 17, a preliminary anti-ferroelectric pattern 330P may be formed within the gate dielectric recess 300R.

The preliminary anti-ferroelectric pattern 330P may be formed within the inner sidewall and the gate dielectric recess 300R of the first channel hole CT1. That is, the preliminary anti-ferroelectric pattern 330P may be conformally formed on the side surfaces of the plurality of interlayer insulating layers 132m, side surfaces of the plurality of sacrificial insulating layers 130s exposed by the gate dielectric recess 300R, portions of upper surfaces of the plurality of interlayer insulating layers 132m, and portions of lower surfaces of the plurality of interlayer insulating layers 132m. Accordingly, the preliminary anti-ferroelectric pattern 330P may include portions formed on side surfaces of the plurality of interlayer insulating layers 132m extending in the third direction (the Z direction) and a portion formed within the gate dielectric recess 300R. The preliminary anti-ferroelectric pattern 330P may be formed to a sufficient thickness to completely cover or overlap a side surface of the gate dielectric recess 300R. In other words, the preliminary anti-ferroelectric pattern 330P may completely cover or overlap the side surfaces of the plurality of sacrificial insulating layers 130s exposed by the gate dielectric recess 300R. The preliminary anti-ferroelectric pattern 330P may be formed with a certain thickness, but the present disclosure is not limited thereto.

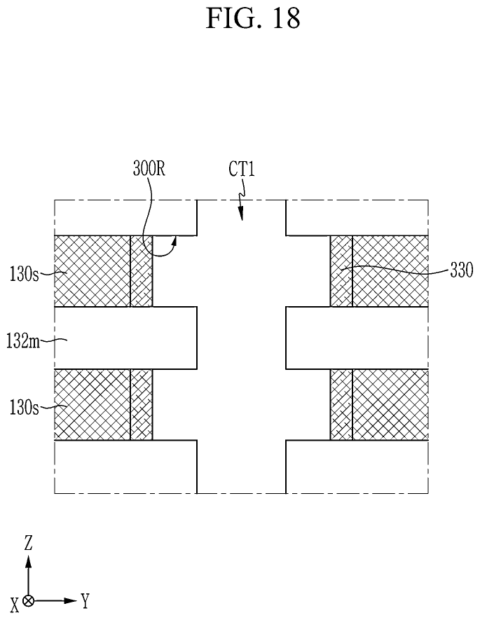

Referring to FIG. 18, the anti-ferroelectric pattern 330 may be formed by removing at least a portion of the preliminary anti-ferroelectric pattern 330P.

Specifically, a portion of the preliminary anti-ferroelectric pattern 330P formed within the first channel hole CT1, a portion of the preliminary anti-ferroelectric pattern 330P formed on upper surfaces of the plurality of interlayer insulating layers 132m, and a portion of the preliminary anti-ferroelectric pattern 330P formed on lower surfaces of the plurality of interlayer insulating layers 132m, may be removed. In this case, a process of removing at least a portion of the preliminary anti-ferroelectric pattern 330P may be performed using a wet etching process, but the present disclosure is not limited thereto.

As at least a portion of the preliminary anti-ferroelectric pattern 330P is removed, the anti-ferroelectric pattern 330 may be formed within the gate dielectric recess 300R. Because the anti-ferroelectric pattern 330 is formed within the gate dielectric recess 300R, the plurality of anti-ferroelectric patterns 330 may be provided to be spaced apart from each other at a predetermined interval in the third direction (the Z direction). In other words, the anti-ferroelectric pattern 330 may overlap the plurality of gate electrodes 130 in the radius direction of the channel structure CH, and may not overlap the plurality of interlayer insulating layers 132m in the radius direction of the channel structure CH.

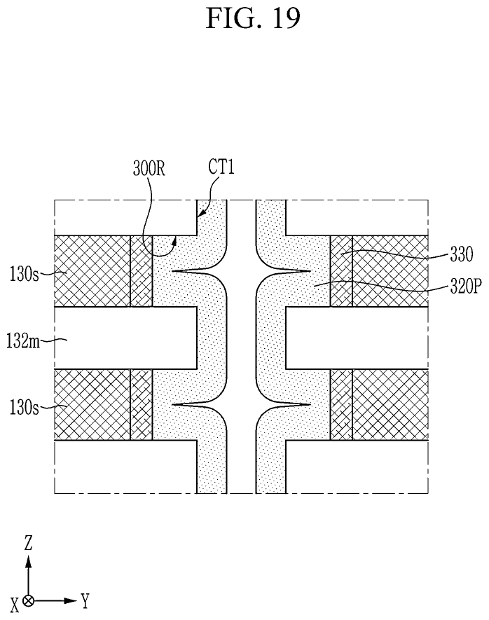

Referring to FIG. 19, a preliminary ferroelectric pattern 320P may be formed on the side surface of the anti-ferroelectric pattern 330.

Specifically, the preliminary ferroelectric pattern 320P may be formed within the inner sidewall and the gate dielectric recess 300R of the first channel hole CT1. That is, the preliminary ferroelectric pattern 320P may be conformally formed on side surfaces of the plurality of interlayer insulating layers 132m, a side surface of the anti-ferroelectric pattern 330 exposed by the gate dielectric recess 300R, portions of upper surfaces of the plurality of interlayer insulating layers 132m, and portions of lower surfaces of the plurality of interlayer insulating layers 132m. Accordingly, the preliminary ferroelectric pattern 320P may include portions formed on side surfaces of the plurality of interlayer insulating layers 132m extending in the third direction (the Z direction) and a portion formed within the gate dielectric recess 300R. The preliminary ferroelectric pattern 320P may be formed to a sufficient thickness to completely cover or overlap a side surface of the gate dielectric recess 300R. In other words, the preliminary ferroelectric pattern 320P may completely cover or overlap the side surface of the anti-ferroelectric pattern 330 exposed by the gate dielectric recess 300R. The preliminary ferroelectric pattern 320P may be formed with a certain thickness, but the present disclosure is not limited thereto.

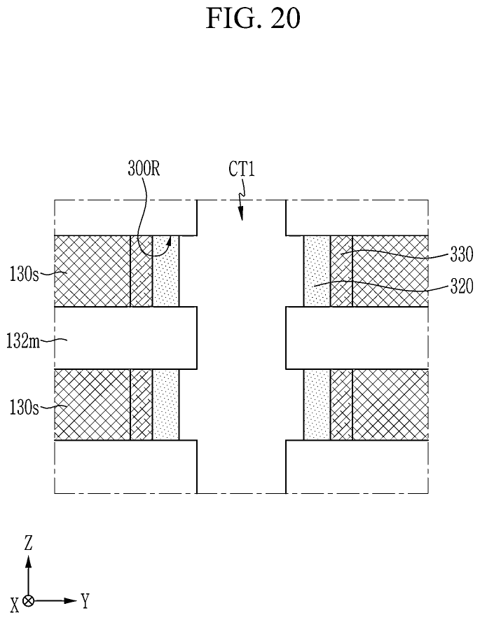

Referring to FIG. 20, the ferroelectric pattern 320 may be formed by removing at least a portion of the preliminary ferroelectric pattern 320P.

Specifically, a portion of the preliminary ferroelectric pattern 320P formed within the first channel hole CT1, a portion of the preliminary ferroelectric pattern 320P formed on upper surfaces of the plurality of interlayer insulating layers 132m, and a portion of the preliminary ferroelectric pattern 320P formed on lower surfaces of the plurality of interlayer insulating layers 132m, may be removed. In this case, a process of removing at least a portion of the preliminary ferroelectric pattern 320P may be performed using a wet etching process, but the present disclosure is not limited thereto.

As at least a portion of the preliminary ferroelectric pattern 320P is removed, the anti-ferroelectric pattern 330 may be formed within the gate dielectric recess 300R. Because the anti-ferroelectric pattern 330 is formed within the gate dielectric recess 300R, the plurality of anti-ferroelectric patterns 330 may be provided to be spaced apart from each other at a predetermined interval in the third direction (the Z direction). In other words, the anti-ferroelectric pattern 330 may overlap the plurality of gate electrodes 130 in the radius direction of the channel structure CH, and may not overlap the plurality of interlayer insulating layers 132m in the radius direction of the channel structure CH.

In this case, because the anti-ferroelectric pattern 330 and the ferroelectric pattern 320 are formed within the gate dielectric recess 300R, an upper surface of the anti-ferroelectric pattern 330 and an upper surface of the ferroelectric pattern 320 may be aligned with upper surfaces of the plurality of sacrificial insulating layers 130s. Additionally, a lower surface of the anti-ferroelectric pattern 330 and a lower surface of the ferroelectric pattern 320 may be aligned with the upper surfaces of the plurality of sacrificial insulating layers 130s.

Although the ferroelectric pattern 320 is described as being formed as a single layer in the embodiment, the present disclosure is not limited thereto, and the ferroelectricity material may be formed as multiple layers as shown in the embodiment of FIG. 12.

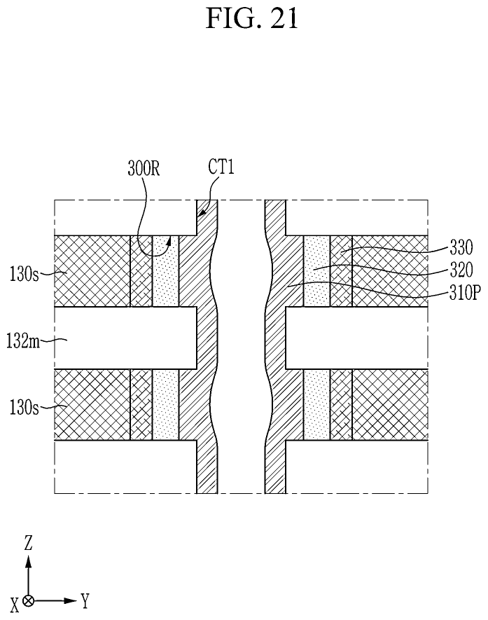

Referring to FIG. 21, a preliminary conductive pattern 310P may be formed on a side surface of the ferroelectric pattern 320.

Specifically, the preliminary conductive pattern 310P may be formed within the inner sidewall and the gate dielectric recess 300R of the first channel hole CT1. That is, the preliminary conductive pattern 310P may be conformally formed on side surfaces of the plurality of interlayer insulating layers 132m, a side surface of the ferroelectric pattern 320 exposed by the gate dielectric recess 300R, portions of upper surfaces of the plurality of interlayer insulating layers 132m, and portions of lower surfaces of the plurality of interlayer insulating layers 132m. Accordingly, the preliminary conductive pattern 310P may include portions formed on side surfaces of the plurality of interlayer insulating layers 132m extending in the third direction (the Z direction) and a portion formed within the gate dielectric recess 300R. The preliminary conductive pattern 310P may be formed to a sufficient thickness to completely cover or overlap a side surface of the gate dielectric recess 300R. In other words, the preliminary conductive pattern 310P may completely cover or overlap the side surface of the ferroelectric pattern 320 exposed by the gate dielectric recess 300R. The preliminary conductive pattern 310P may be formed with a certain thickness, but the present disclosure is not limited thereto.

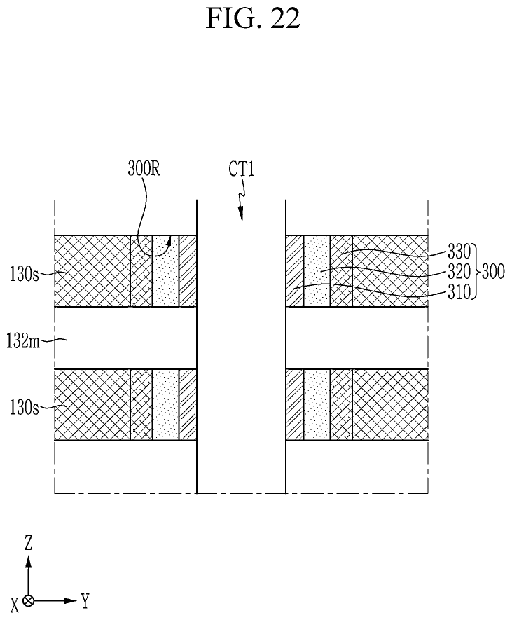

Referring to FIG. 22, the conductive pattern 310 may be formed by removing at least a portion of the preliminary conductive pattern 310P.

Specifically, the portion of the preliminary conductive pattern 310P formed within the first channel hole CT1 may be removed. In this case, a process of removing at least a portion of the preliminary conductive pattern 310P may be performed using a wet etching process, but the present disclosure is not limited thereto.

As at least a portion of the preliminary conductive pattern 310P is removed, the conductive pattern 310 may be formed within the gate dielectric recess 300R. Because the conductive pattern 310 is formed within the gate dielectric recess 300R, the plurality of conductive patterns 310 may be provided to be spaced apart from each other at a predetermined interval in the third direction (the Z direction). That is, the conductive pattern 310 may overlap the plurality of gate electrodes 130 in the radius direction of the channel structure CH, and may not overlap the plurality of interlayer insulating layers 132m in the radius direction of the channel structure CH.

In this case, because the anti-ferroelectric pattern 330, the ferroelectric pattern 320, and the conductive pattern 310 are formed within the gate dielectric recess 300R, an upper surface of the anti-ferroelectric pattern 330, an upper surface of the ferroelectric pattern 320, and an upper surface of the conductive pattern 310 may be aligned with upper surfaces of the plurality of sacrificial insulating layers 130s. Additionally, a lower surface of the anti-ferroelectric pattern 330, a lower surface of the ferroelectric pattern 320, and a lower surface of the conductive pattern 310 may be aligned with the upper surfaces of the plurality of sacrificial insulating layers 130s.

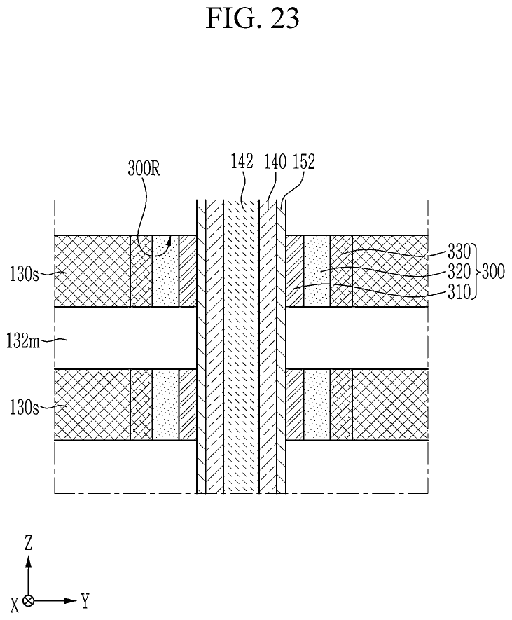

Referring to FIG. 23, the channel structure CH may be formed within the first channel hole CT1. The channel insulating layer 152, the channel layer 140, and the core insulating layer 142 may be sequentially stacked within the first channel hole CT1.

The channel insulating layer 152, the channel layer 140, and the core insulating layer 142 may be formed to have a predetermined thickness and to have a conformal shape within the first channel hole CT1. The channel insulating layer 152, the channel layer 140, and the core insulating layer 142 may be formed to cover or overlap the inner sidewall and a bottom surface of the first channel hole CT1. The channel insulating layer 152 and the channel layer 140 may not be completely inside of or completely fill the first channel hole CT1. A portion of the first channel hole CT1 that is not filled by or does not include the channel insulating layer 152 and the channel layer 140 may be filled by or include the core insulating layer 142. Although not shown in the drawings, a channel pad may be formed above or on the channel insulating layer 152, the channel layer 140, and the core insulating layer 142.

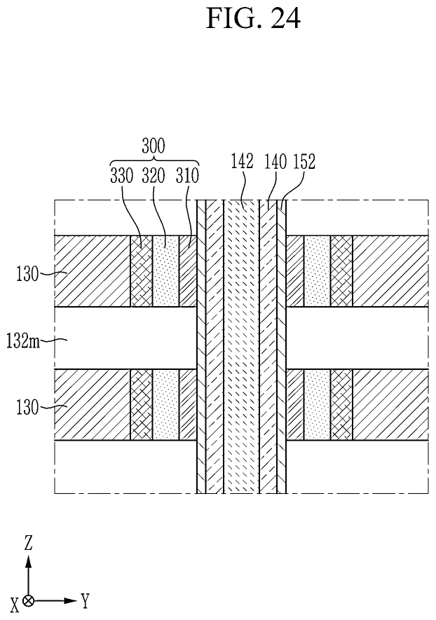

Referring to FIG. 24, the plurality of sacrificial insulating layers 130s may be removed, and the plurality of gate electrodes 130 may be formed within a space where the plurality of sacrificial insulating layers 130s are removed. For example, after the plurality of sacrificial insulating layers 130s are removed using an etching process, the plurality of gate electrodes 130 may be formed by depositing a metal material, such as tungsten (W), copper (Cu), aluminum (Al), or the like. The plurality of gate electrodes 130 may include the lower gate electrode 130L, the memory cell gate electrode 130M, and the upper gate electrode 130U sequentially disposed above the second substrate 110. The lower gate electrode 130L may be used as a gate electrode of a ground selection transistor, the memory cell gate electrode 130M may constitute the memory cell, and the upper gate electrode 130U may be used as a gate electrode of a string selection transistor. Accordingly, the semiconductor device 10 of FIGS. 1 to 6 may be formed.

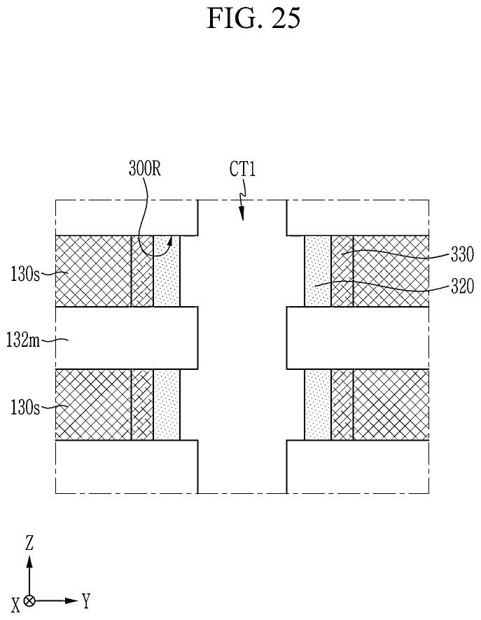

Next, the method for manufacturing the semiconductor device according to some embodiments will be described with reference to FIGS. 25 to 28.

FIGS. 25 to 28 are cross-sectional views sequentially showing the method for manufacturing the semiconductor device according to some embodiments and corresponding to the region S2 of FIG. 14.

Hereinafter, the method for manufacturing the plurality of dielectric layers 300 of the semiconductor device according to some embodiments will be mainly described. Additionally, the method of manufacturing the semiconductor device according to some embodiments shown in FIGS. 25 to 28 is similar to the method of manufacturing the semiconductor device according to some embodiments shown in FIGS. 13 to 24, so that a description thereof will be omitted and a difference between the embodiment of FIGS. 25 to 28 and the embodiment of FIGS. 13 to 24 will be mainly described. In addition, the same reference numeral is used for a component that is the same as that of the previous embodiments. The present embodiment may be different from the previous embodiment in that the present embodiment forms the conductive pattern 310, and will be described below.

Referring to FIG. 25, the anti-ferroelectric pattern 330 and the ferroelectric pattern 320 may be formed within the gate dielectric recess 300R. Because a process of forming the anti-ferroelectric pattern 330 and the ferroelectric pattern 320 is substantially the same as a process of forming the anti-ferroelectric pattern 330 and the ferroelectric pattern 320 according to some embodiments of FIGS. 13 to 24, a description thereof will be omitted.

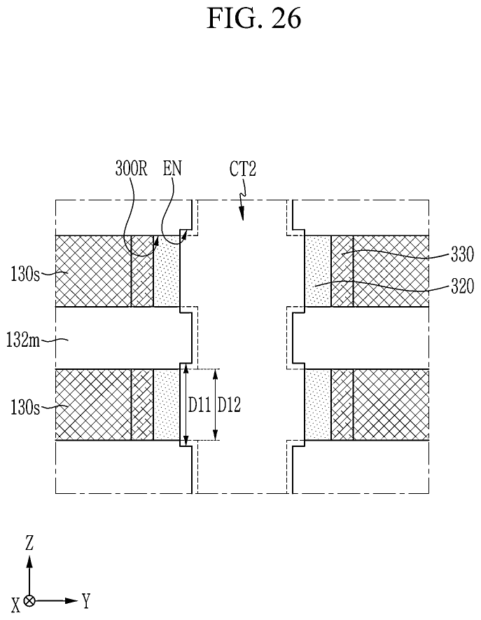

Referring to FIG. 26, portions of the plurality of interlayer insulating layers 132m may be etched to form an extension portion (or an expansion portion) EN.

Specifically, side surfaces of the plurality of interlayer insulating layers 132m exposed by the first channel hole CT1 and portions of upper surfaces and portions of lower surfaces of the plurality of interlayer insulating layers 132m exposed by the gate dielectric recess 300R may be etched. A process of removing the portions of the plurality of interlayer insulating layers 132m may be performed using a wet etching process, but the present disclosure is not limited thereto. Additionally, the plurality of interlayer insulating layers 132m may include a material having etching selectivity with respect to the ferroelectric pattern 320. Accordingly, during a process of etching the plurality of interlayer insulating layers 132m, the ferroelectric pattern 320 may not be etched.

The extension portion EN may be formed by etching the portions of the upper surfaces and the portions of the lower surfaces of the plurality of interlayer insulating layers 132m exposed by the gate dielectric recess 300R. For example, a first interval D11 of the extension portion EN along the third direction (the Z direction) may be larger than a second interval D12 of the gate dielectric recess 300R in the third direction (the Z direction). Additionally, an upper surface of the extension portion EN may be disposed at a higher level than an upper surface of the gate dielectric recess 300R. A lower surface of the extension portion EN may be disposed at a lower level than a lower surface of the gate dielectric recess 300R. Additionally, a second channel hole CT2 may be formed as the side surfaces of the plurality of interlayer insulating layers 132m exposed by the first channel hole CT1 are etched.

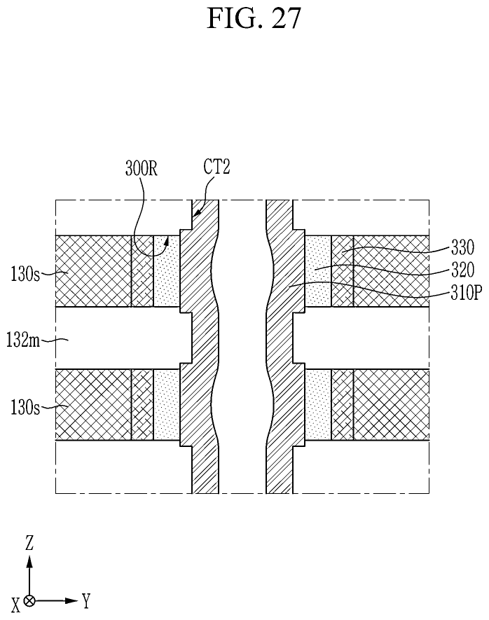

Referring to FIG. 27, the preliminary conductive pattern 310P may be formed within the extension portion EN and the second channel hole CT2.

Specifically, the preliminary conductive pattern 310P may be formed within an inner sidewall of the second channel hole CT2 and the extension portion EN. That is, the preliminary conductive pattern 310P may be conformally formed on the side surfaces of the plurality of interlayer insulating layers 132m, a side surface of the ferroelectric pattern 320 exposed by the extension portion EN, and portions of upper surfaces and portions of lower surfaces of the plurality of interlayer insulating layers 132m. Accordingly, the preliminary conductive pattern 310P may include a portion formed on the side surfaces of the plurality of interlayer insulating layers 132m extending in the third direction (the Z direction) and a portion formed within the extension portion EN. The preliminary conductive pattern 310P may be formed to a sufficient thickness to completely cover or overlap a side surface of the extension portion EN. That is, the preliminary conductive pattern 310P may completely cover or overlap the side surface of the ferroelectric pattern 320 exposed by the extension portion EN. The preliminary conductive pattern 310P may be formed with a certain thickness, but the present disclosure is not limited thereto.

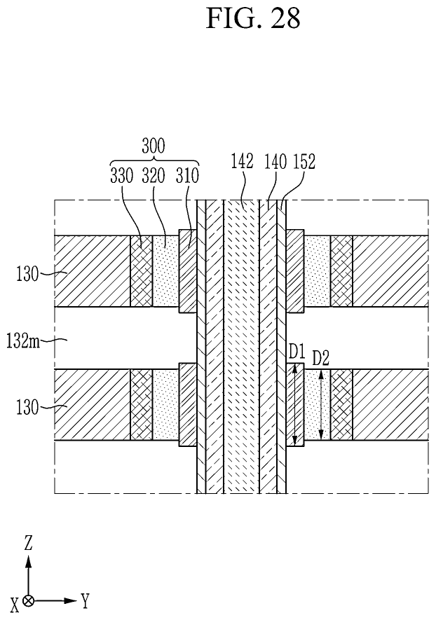

Referring to FIG. 28, the conductive pattern 310 may be formed by removing at least a portion of the preliminary conductive pattern 310P, the channel structure CH may be formed within the second channel hole CT2, and the plurality of sacrificial insulating layers 130s may be removed and the plurality of gate electrodes 130 may be formed.

First, a portion of the preliminary conductive pattern 310P formed within the second channel hole CT2 may be removed. In this case, a process of removing at least a portion of the preliminary conductive pattern 310P may be performed using a wet etching process, but the present disclosure is not limited thereto.

As at least a portion of the preliminary conductive pattern 310P is removed, the conductive pattern 310 may be formed within the extension portion EN. Because the conductive pattern 310 is formed within the extension portion EN, the plurality of conductive patterns 310 may be provided to be spaced apart from each other at a predetermined interval in the third direction (the Z direction). That is, the conductive pattern 310 may overlap the plurality of gate electrodes 130 in the radius direction of the channel structure CH, and may not overlap the plurality of interlayer insulating layers 132m in the radius direction of the channel structure CH.

In this case, the first width D1 of the conductive pattern 310 according to some embodiments in the third direction (the Z direction) may be larger than the second width D2 of the ferroelectric pattern 320 in the third direction (the Z direction).

In some embodiments, an upper surface of the conductive pattern 310 may be disposed at a higher level than an upper surface of the ferroelectric pattern 320 and an upper surface of the anti-ferroelectric pattern 330. That is, the upper surface of the conductive pattern 310 may be disposed farther from an upper surface of the second substrate 110 than the upper surface of the ferroelectric pattern 320 and the upper surface of the anti-ferroelectric pattern 330. Additionally, a lower surface of the conductive pattern 310 may be disposed at a lower level than a lower surface of the ferroelectric pattern 320 and a lower surface of the anti-ferroelectric pattern 330. That is, the lower surface of the conductive pattern 310 may be disposed closer to the upper surface of the second substrate 110 than the lower surface of the ferroelectric pattern 320 and the lower surface of the anti-ferroelectric pattern 330. Accordingly, the first width D1 of the conductive pattern 310 in the third direction (the Z direction) may be larger than the second width D2 of the ferroelectric pattern 320 in the third direction (the Z direction). However, even in this case, the plurality of conductive patterns 310 may be provided to be spaced apart from each other at a predetermined interval in the third direction (the Z direction).

Subsequently, the channel insulating layer 152, the channel layer 140, and the core insulating layer 142 may be sequentially stacked within the second channel hole CT2. The channel insulating layer 152, the channel layer 140, and the core insulating layer 142 may be formed to have a predetermined thickness and have a conformal shape within the second channel hole CT2. Because a process of forming the channel insulating layer 152, the channel layer 140, and the core insulating layer 142 is substantially the same as a process of forming the channel insulating layer 152, the channel layer 140, and the core insulating layer 142 according to some embodiments of FIGS. 13 to 21, a description thereof will be omitted.

Finally, the plurality of sacrificial insulating layers 130s may be removed, and the plurality of gate electrodes 130 may be formed within a space where the plurality of sacrificial insulating layers 130s are removed. For example, after the plurality of sacrificial insulating layers 130s are removed using an etching process, the plurality of gate electrodes 130 may be formed by depositing a metal material such as tungsten (W), copper (Cu), aluminum (Al), or the like. Because a process of forming the plurality of gate electrodes 130 is substantially the same as a process of forming the plurality of gate electrodes 130 of the embodiment of FIGS. 13 to 21, a description thereof will be omitted. Accordingly, the semiconductor device 10 of FIG. 8 may be formed.

Next, the electronic system including the semiconductor device according to some embodiments will be described with reference to FIG. 29.

FIG. 29 is a view schematically showing the electronic system including the semiconductor device according to some embodiments.

As shown in FIG. 29, the electronic system 1000 according to some embodiments may include the semiconductor device 1100 and a controller 1200 electrically connected to the semiconductor device 1100. The electronic system 1000 may be a storage device including one or a plurality of semiconductor devices 1100 or an electronic device including the storage device. For example, the electronic system 1000 may be a solid state drive (SSD) device including one or a plurality of semiconductor devices 1100, a Universal Serial Bus (USB), a computing system, a medical device, or a communication device.

The semiconductor device 1100 may be a non-volatile memory device, and for example, may be a NAND flash memory device described with reference to FIGS. 1 to 11. The semiconductor device 1100 may include the first structure 1100F and the second structure 1100S on the first structure 1100F. In some embodiments, the first structure 1100F may be disposed next to the second structure 1100S. The first structure 1100F may be the peripheral circuit structure including the decoder circuit 1110, the page buffer 1120, and the logic circuit 1130. The second structure 1100S may be a memory cell structure including a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously modified according to some embodiments.

In some embodiments, the lower transistors LT1 and LT2 may include a ground selection transistor, and the upper transistors UT1 and UT2 may include a string selection transistor. The first and second gate lower lines LL1 and LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected to the decoder circuit 1110 through a first connection wire 1115 extending to the second structure 1100S within the first structure 1100F. The bit line BL may be electrically connected to the page buffer 1120 through a second connection wire 1125 extending to the second structure 1100S within the first structure 1100F.

In the first structure 1100F, the decoder circuit 1110 and the page buffer 1120 may execute a control operation for at least one memory cell transistor selected from among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection wire 1135 extending to the second structure 1100S within the first structure 1100F.

The controller 1200 may include a processor 1210, a NAND controller 1220, and a host interface 1230. According to some embodiments, the electronic system 1000 may include the plurality of semiconductor devices 1100, and in this case, the controller 1200 may control the plurality of semiconductor devices 1100.

The processor 1210 may control an overall operation of the electronic system 1000 including the controller 1200. The processor 1210 may operate according to predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be written in the memory cell transistor MCT of the semiconductor device 1100, and data to be read from the memory cell transistor MCT of the semiconductor device 1100, or the like may be transmitted through the NAND interface 1221. The host interface 1230 may provide a communication function between the electronic system 1000 and an external host. If a control command is received from the external host through the host interface 1230, the processor 1210 may control the semiconductor device 1100 in response to the control command.

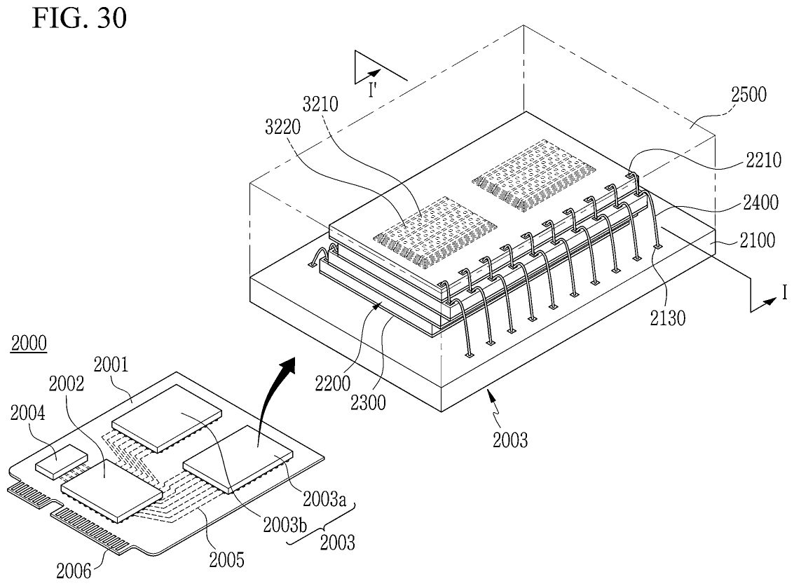

FIG. 30 is a perspective view schematically showing an electronic system including the semiconductor device according to some embodiments.

As shown in FIG. 30, the electronic system 2000 according to some embodiments may include a main substrate 2001, a controller 2002 mounted on the main substrate 2001, one or more semiconductor packages 2003, and a DRAM 2004. The semiconductor package 2003 and the DRAM 2004 may be connected to the controller 2002 through a wiring pattern 2005 formed at the main substrate 2001.

The main substrate 2001 may include a connector 2006 including a plurality of pins coupled to the external host. The number and a disposition of the plurality of pins in the connector 2006 may vary depending on a communication interface between the electronic system 2000 and the external host. In some embodiments, the electronic system 2000 may communicate with the external host according to any one of interfaces such as a universal serial bus (USB), a peripheral component interconnect express (PCI-Express), a serial advanced technology attachment (SATA), an M-Phy for a universal flash storage (UFS), and the like. In some embodiments, the electronic system 2000 may operate with a power supply supplied from the external host through the connector 2006. The electronic system 2000 may further include a power management integrated circuit (PMIC) that distributes the power supply supplied from the external host to the controller 2002 and the semiconductor package 2003.

The controller 2002 may write data in the semiconductor package 2003 or may read data from the semiconductor package 2003, and may improve an operating speed of the electronic system 2000.

The DRAM 2004 may be a buffer memory for mitigating a speed difference between the semiconductor package 2003, which is a data storage space, and the external host. The DRAM 2004 included in the electronic system 2000 may also operate as a kind of cache memory, and may also provide a space for temporarily storing data in a control operation for the semiconductor package 2003. If the electronic system 2000 includes the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chip 2200 above or on the package substrate 2100, an adhesive layer 2300 disposed at a lower surface of each semiconductor chip 2200, a connection structure 2400 electrically connecting the semiconductor chip 2200 and the package substrate 2100, and a molding layer 2500 covering or overlapping the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 29. Each semiconductor chip 2200 may include a gate stacking structure 3210 and a channel structure 3220. The semiconductor chip 2200 may include the semiconductor device described with reference to FIGS. 1 to 11.

In some embodiments, the connection structure 2400 may be a bonding wire electrically connecting the input/output pad 2210 and the package upper pad 2130. Accordingly, in each of the first and second semiconductor packages 2003a and 2003b, the semiconductor chips 2200 may be electrically connected to each other using a bonding wire method, and the semiconductor chip 2200 may be electrically connected to the package upper pad 2130 of the package substrate 2100. According to some embodiments, in each of the first and second semiconductor packages 2003a and 2003b, the semiconductor chips 2200 may be electrically connected to each other by a connection structure including a through silicon via (TSV) instead of the connection structure 2400 using a bonding wire method.

In some embodiments, the controller 2002 and the semiconductor chip 2200 may be included in one package. For example, the controller 2002 and the semiconductor chip 2200 may be mounted at a separate interposer substrate that is different from the main substrate 2001, and the controller 2002 and the semiconductor chip 2200 may be connected to each other by a wire formed at the interposer substrate.

FIG. 31 and FIG. 32 are cross-sectional views schematically showing a semiconductor package according to some embodiments, respectively. FIG. 31 and FIG. 32 respectively describe the embodiment of the semiconductor package 2003 of FIG. 30, and conceptually show a region obtained by cutting the semiconductor package 2003 of FIG. 30 along a line I-I′.

Referring to FIG. 31, in the semiconductor package 2003, the package substrate 2100 may be a printed circuit board. The package substrate 2100 may include a package substrate body portion 2120, the package upper pad 2130 disposed at an upper surface of the package substrate body portion 2120, a lower pad 2125 disposed at a lower surface of the package substrate body portion 2120 or exposed through the lower surface of the package substrate body portion 2120, and an internal wire 2135 electrically connecting the upper pad 2130 and the lower pad 2125 inside the package substrate body portion 2120. The upper pad 2130 may be electrically connected to the connection structure 2400. The lower pad 2125 may be connected to the wiring pattern 2005 of the main substrate 2001 of the electronic system 2000 of FIG. 30 through a conductive connection portion 2800.

The semiconductor chip 2200 may include a semiconductor substrate 3010 and the first structure 3100 and the second structure 3200 sequentially stacked on the semiconductor substrate 3010. The first structure 3100 may include a peripheral circuit region including a peripheral wire 3110. The second structure 3200 may include a common source line 3205, the gate stacking structure 3210 on the common source line 3205, the channel structure 3220 and a separation structure 3230 penetrating or extending into the gate stacking structure 3210, a bit line 3240 electrically connected to the channel structure 3220, and a gate connection wire electrically connected to the word line WL of FIG. 29 of the gate stacking structure 3210.

In the semiconductor chip 2200 or the semiconductor device according to some embodiments, when a voltage is applied to the plurality of gate electrodes 130, an electric field within the conductive pattern 310 may be distributed with a uniform density. Accordingly, the electric field having the uniform density may be distributed at a portion of the ferroelectric pattern 320 that overlaps the conductive pattern 310 in the radius direction of the channel structure CH, and a remnant polarization may be uniformly generated within the ferroelectric pattern 320. Additionally, when a voltage is applied to the plurality of gate electrodes 130 of the semiconductor device 10 according to some embodiments, a dielectric constant of the anti-ferroelectric pattern 330 may increase so that an electric charge is concentrated within the anti-ferroelectric pattern 330. Additionally, the plurality of dielectric layers 300 according to some embodiments may be disposed apart from each other along the third direction (the Z direction). Therefore, it is possible to prevent interference between the plurality of dielectric layers 300 disposed apart from each other in the third direction (the Z direction). Accordingly, the reliability of the semiconductor device 10 may be improved.

Each of the semiconductor chips 2200 may include a through wire 3245 that is electrically connected to the peripheral wire 3110 of the first structure 3100 and extends into the second structure 3200. The through wire 3245 may pass through or extend into the gate stacking structure 3210, and may be further disposed outside the gate stacking structure 3210. Each semiconductor chip 2200 may further include an input/output connection wire 3265 electrically connected to the peripheral wire 3110 of the first structure 3100 and extending into the second structure 3200, and the input/output pad 2210 electrically connected to the input/output connection wire 3265.

In some embodiments, in the semiconductor package 2003, the plurality of semiconductor chips 2200 may be electrically connected to each other by the connection structure 2400 having a bonding wire form. As another example, the plurality of semiconductor chips 2200 or a plurality of portions constituting the semiconductor chips 2200 may be electrically connected by a connection structure including a through silicon via (TSV).

Referring to FIG. 32, in a semiconductor package 2003A, each semiconductor chip 2200 may include a semiconductor substrate 4010, a first structure 4100 on the semiconductor substrate 4010, and the second structure 4200 bonded to the first structure 4100 by a wafer bonding method on the first structure 4100.

The first structure 4100 may include a peripheral circuit region including a peripheral wire 4110 and a first bonding structure 4150. The second structure 4200 may include a common source line 4205, a gate stacking structure 4210 between the common source line 4205 and the first structure 4100, a channel structure 4220 and a separation structure 4230 passing through or extending into the gate stacking structure 4210, and a second bonding structure 4250 electrically connected to the channel structure 4220 and the word line WL of FIG. 29 of the gate stacking structure 4210. For example, the second bonding structure 4250 may be electrically connected to the channel structure 4220 and the word line WL through a bit line 4240 electrically connected to the channel structure 4220 and the gate connection wire electrically connected to the word line WL. The first bonding structure 4150 of the first structure 4100 and the second bonding structure 4250 of the second structure 4200 may be bonded while contacting each other. For example, a portion where the first bonding structure 4150 and the second bonding structure 4250 are bonded may be formed of copper (Cu).

In the semiconductor chip 2200 or the semiconductor device according to some embodiments, when a voltage is applied to the plurality of gate electrodes 130, an electric field within the conductive pattern 310 may be distributed with a uniform density. Accordingly, the electric field having the uniform density may be distributed at a portion of the ferroelectric pattern 320 that overlaps the conductive pattern 310 in the radius direction of the channel structure CH, and a remnant polarization may be uniformly generated within the ferroelectric pattern 320. Additionally, when a voltage is applied to the plurality of gate electrodes 130 of the semiconductor device 10 according to some embodiments, a dielectric constant of the anti-ferroelectric pattern 330 may increase so that an electric charge is concentrated within the anti-ferroelectric pattern 330. Additionally, the plurality of dielectric layers 300 according to some embodiments may be disposed apart from each other in the third direction (the Z direction). Therefore, it is possible to prevent interference between the plurality of dielectric layers 300 disposed apart from each other in the third direction (the Z direction). Accordingly, the reliability of the semiconductor device 10 may be improved.

Each semiconductor chip 2200 may further include the input/output pad 2210 and an input/output connection wire 4265 below the input/output pad 2210. The input/output connection wire 4265 may be electrically connected to a portion of the second bonding structure 4250.

In some embodiments, in the semiconductor package 2003, the plurality of semiconductor chips 2200 may be electrically connected to each other by the connection structure 2400 having a bonding wire form. As another example, the plurality of semiconductor chips 2200 or a plurality of portions constituting the semiconductor chips 2200 may be electrically connected by a connection structure including a through silicon via (TSV).

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor device comprising:
a substrate;
a gate stacking structure that comprises a plurality of interlayer insulating layers and a plurality of gate electrodes that are alternately stacked on the substrate;
a channel layer that extends in a first direction and into the gate stacking structure, wherein the channel layer is electrically connected to the substrate;
a channel insulating layer that at least partially surrounds the channel layer; and
a plurality of dielectric layers that are between the channel insulating layer and the plurality of gate electrodes, extend along a circumference of the channel layer, and are spaced apart from each other in the first direction,
wherein each of the plurality of dielectric layers comprises:
a ferroelectric pattern that at least partially surrounds the channel insulating layer; and
an anti-ferroelectric pattern that at least partially surrounds the ferroelectric pattern.

2. The semiconductor device of claim 1, wherein each of the plurality of dielectric layers is between a respective pair of the plurality of interlayer insulating layers.

3. The semiconductor device of claim 1, wherein a thickness of the ferroelectric pattern in a second direction is greater than a thickness of the anti-ferroelectric pattern in the second direction.

4. The semiconductor device of claim 1, wherein an upper surface of the ferroelectric pattern, an upper surface of the anti-ferroelectric pattern, and an upper surface of each of the plurality of gate electrodes are coplanar, and wherein a lower surface of the ferroelectric pattern, a lower surface of the anti-ferroelectric pattern, and a lower surface of each of the plurality of gate electrodes are coplanar.

5. The semiconductor device of claim 1, wherein each of the plurality of dielectric layers further comprises a conductive pattern that is between the channel insulating layer and the ferroelectric pattern or that is between the ferroelectric pattern and the anti-ferroelectric pattern.

6. The semiconductor device of claim 5, wherein the conductive pattern extends along the circumference of the channel layer.

7. The semiconductor device of claim 5, wherein a length of the conductive pattern in the first direction is greater than or equal to a length of the ferroelectric pattern in the first direction.

8. The semiconductor device of claim 5, wherein the conductive pattern comprises a metal, a metal nitride, a metal oxide, or a combination thereof.

9. The semiconductor device of claim 8, wherein the conductive pattern and the plurality of gate electrodes comprise a same material.

10. The semiconductor device of claim 1, wherein the plurality of dielectric layers overlap respective ones of the plurality of gate electrodes in a second direction, and wherein the plurality of dielectric layers do not overlap the plurality of interlayer insulating layers in the second direction.

11. The semiconductor device of claim 1, wherein the ferroelectric pattern comprises a first ferroelectric pattern on an exterior side surface of the channel layer, a second ferroelectric pattern that at least partially surrounds the first ferroelectric pattern, and an interface insertion film between the first ferroelectric pattern and the second ferroelectric pattern, and wherein at least one of the first ferroelectric pattern or the second ferroelectric pattern comprises HfSiO, HfO₂, HfZnO, HfSiON, HfTaO, HfTiO, HfZrO, or a combination thereof.

12. The semiconductor device of claim 11, wherein the first ferroelectric pattern, the second ferroelectric pattern, and the interface insertion film comprises HfSiO, and a Si concentration of the interface insertion film is greater than a Si concentration of the first ferroelectric pattern and a Si concentration of the second ferroelectric pattern.

13. A semiconductor device comprising:
a substrate;
a gate stacking structure that comprises a plurality of interlayer insulating layers and a plurality of gate electrodes that are alternately stacked on the substrate;
a channel layer that extends in a first direction and into the gate stacking structure, wherein the channel layer is electrically connected to the substrate;
a channel insulating layer that at least partially surrounds the channel layer; and
a plurality of dielectric layers that are between the channel insulating layer and the plurality of gate electrodes, extend along a circumference of the channel layer, and are spaced apart from each other in the first direction,
wherein each of the plurality of dielectric layers comprises:
a conductive pattern that at least partially surrounds the channel insulating layer;
a ferroelectric pattern that at least partially surrounds the conductive pattern; and
an anti-ferroelectric pattern between the ferroelectric pattern and a respective one of the plurality of gate electrodes.

14. The semiconductor device of claim 13, wherein the plurality of dielectric layers overlap respective ones of the plurality of gate electrodes in a second direction, and wherein the plurality of dielectric layers do not overlap the plurality of interlayer insulating layers in the second direction.

15. The semiconductor device of claim 14, wherein a thickness of the ferroelectric pattern in the second direction is greater than a thickness of the conductive pattern in the second direction.

16. The semiconductor device of claim 14, wherein a thickness of the ferroelectric pattern in the second direction is greater than a thickness of the anti-ferroelectric pattern in the second direction.

17. The semiconductor device of claim 14, wherein a length of the conductive pattern in the first direction is greater than or equal to a length of the ferroelectric pattern in the first direction.

18. An electronic system comprising:
a main substrate;
a semiconductor device on the main substrate; and
a controller that is electrically connected to the semiconductor device,
wherein the semiconductor device comprises:
a peripheral circuit region,
a cell region that comprises an input/output connection wire that is electrically connected to the peripheral circuit region, and
an input/output pad that is electrically connected to the input/output connection wire and extends into the cell region,
wherein the cell region comprises:
a substrate,
a gate stacking structure that comprises a plurality of interlayer insulating layers and a plurality of gate electrodes that are alternately stacked on the substrate,
a channel layer that extends in a first direction and into the gate stacking structure, wherein the channel layer is electrically connected to the substrate,
a channel insulating layer that at least partially surrounds the channel layer, and
a plurality of dielectric layers that are between the channel insulating layer and the plurality of gate electrodes, extend along a circumference of the channel layer, and are spaced apart from each other in the first direction, and
wherein each of the plurality of dielectric layers comprises a ferroelectric pattern that at least partially surrounds the channel insulating layer and an anti-ferroelectric pattern that at least partially surrounds the ferroelectric pattern.

19. The electronic system of claim 18, wherein each of the plurality of dielectric layers further comprises a conductive pattern that is between the channel insulating layer and the ferroelectric pattern or that is between the ferroelectric pattern and the anti-ferroelectric pattern.

20. The semiconductor device of claim 19, wherein a length of the conductive pattern in the first direction is greater than or equal to a length of the ferroelectric pattern in the first direction.
